(19) United States
(12) Patent Application Publication
(10) Pub. No.: US 2024/0306433 A1
(43) Pub. Date: Sep. 12, 2024

(54) DISPLAY PANEL AND METHOD OF MANUFACTURING SAME

(71) Applicant: Samsung Display Co., LTD., Yongin-si (KR)

(72) Inventors: Hyuneok SHIN, Yongin-si (KR); Joonyong PARK, Yongin-si (KR); Dongmin LEE, Yongin-si (KR)

(21) Appl. No.: 18/530,892

(22) Filed: Dec. 6, 2023

(30) Foreign Application Priority Data
Mar. 7, 2023 (KR) 10-2023-0030186

(51) Int. Cl. H10K 59/122; H10K 59/12; H10K 59/80

(52) U.S. Cl. CPC H10K 59/122; H10K 59/1201; H10K 59/80521

(57) ABSTRACT

A display panel includes a first anode, a pixel definition layer in which a first light-emitting opening is defined, a partition wall which includes a first partition wall layer and a second partition wall layer, in which a first partition wall opening corresponding to the first light-emitting opening is defined, and which is disposed on the pixel definition layer, a first cover pattern disposed inside the first partition wall opening, a first cathode in contact with the first cover pattern, and a first light-emitting pattern disposed between the first anode and the first cathode. The first cover pattern contacts a lower surface of the second partition wall layer exposed from the first partition wall layer and overlaps an entirety of a portion of the second partition wall layer, which protrudes from the first partition wall layer, in a plan view.

This application claims priority to Korean Patent Application No. 10-2023-0030186, filed on Mar. 7, 2023, and all the benefits accruing therefrom under 35 U.S.C. § 119, the content of which in its entirety is herein incorporated by reference.

### BACKGROUND

### 1. Field

Embodiments of the disclosure described herein relate to a display panel and a method of manufacturing the same, and particularly, to a display panel having improved reliability and a method of manufacturing the same.

### 2. Description of the Related Art

A display device is activated according to an electrical signal. The display device may include a display panel that displays an image. In the display panel, an organic light-emitting display panel has substantially low power consumption, substantially high luminance, and substantially high response speed.

Among the display panel, the organic light-emitting display panel includes an anode, a cathode, and a light-emitting pattern. The light-emitting pattern is separated for each light-emitting area, and the cathode provides a common voltage to each light-emitting area.

### SUMMARY

Embodiments of the disclosure provide a display panel having improved process reliability and easy implementation of a substantially high resolution because a light-emitting element is formed without using a metal mask.

Embodiments of the disclosure also provide a display panel having improved electrical reliability and display efficiency because contact resistance between a cathode and a partition wall is reduced, and a method of manufacturing the same.

In an embodiment, a display panel includes a base layer, a first anode disposed on the base layer, a pixel definition layer in which a first light-emitting opening exposing at least a portion of the first anode is defined and which is disposed on the base layer, a partition wall which includes a first partition wall layer and a second partition wall layer disposed on the first partition wall layer, in which a first partition wall opening corresponding to the first light-emitting opening is defined, and which is disposed on the pixel definition layer, a first cover pattern disposed inside the first partition wall opening, a first cathode in contact with the first cover pattern and disposed on the first anode, and a first light-emitting pattern disposed between the first anode and the first cathode, where the second partition wall layer protrudes from the first partition wall layer so that a lower surface of the second partition wall layer is exposed, and the first cover pattern is in contract with an exposed portion of the lower surface of the second partition wall layer and overlaps an entirety of a portion of the second partition wall layer, which protrudes from the first partition wall layer, in a plan view.

In an embodiment, the first partition wall layer may include a first inner surface defining a first area of the first partition wall opening, the second partition wall layer may include a second inner surface defining a second area of the first partition wall opening, and a width of the second area in one direction may be smaller than a width of the first area in the one direction.

In an embodiment, the first cover pattern may be disposed only in the first area and may not be disposed in the second area.

In an embodiment, the first cover pattern may include a first portion covering an entirety of the exposed portion of the lower surface of the second partition wall layer, and a second portion extending from the first portion and covering an entirety of the first inner surface.

In an embodiment, the first cover pattern may further include a third portion extending from the second portion and covering at least a portion of an upper surface of the pixel definition layer exposed from the first partition wall layer.

In an embodiment, the first cathode may contact the second portion.

In an embodiment, the first cover pattern may include a first portion covering an entirety of the exposed portion of the lower surface of the second partition wall layer, and a second portion extending from the first portion and covering an entirety of an oxide film formed on the first inner surface.

In an embodiment, the first cover pattern may have a closed-line shape in the plan view.

In an embodiment, the first partition wall layer may include one of a conductive material and an insulating material, and each of the second partition wall layer and the first cover pattern may include a conductive material.

In an embodiment, the second partition wall layer may include titanium nitride, and the first cover pattern may include any one of tungsten, molybdenum, and titanium nitride.

In an embodiment, the partition wall may further include a third partition wall layer disposed on the second partition wall layer.

In an embodiment, a modulus of the third partition wall layer may be greater than a modulus of the second partition wall layer.

In an embodiment, a thickness of the first cover pattern may be 100 angstroms (Å) or less.

In an embodiment, the display panel may further include a second anode disposed on the base layer and spaced apart from the first anode, a second cover pattern spaced apart from the first cover pattern, a second cathode disposed on the second anode and in contact with the second cover pattern, and a second light-emitting pattern disposed between the second anode and the second cathode, where a second light-emitting opening exposing at least a portion of the second anode may be further defined in the pixel definition layer, a second partition wall opening corresponding to the second light-emitting opening may be further defined in the partition wall, and the second cover pattern may be disposed inside the second partition wall opening.

In an embodiment, the display panel may further include a sacrificial pattern which is disposed on the first anode, an entirety of which is covered by the pixel definition layer and in which a sacrificial opening corresponding to the first light-emitting opening is defined, and a dummy cover pattern which is disposed inside the sacrificial opening, an entirety of which is covered by the pixel definition layer, and which is spaced apart from the first cover pattern.

In an embodiment, a method of manufacturing a display panel includes providing a preliminary display panel including a base layer, an anode disposed on the base layer, a pixel definition layer which is dispose on the base layer and in which a light-emitting opening exposing at least a portion of the anode is defined, and a partition wall which includes a first partition wall layer disposed on the pixel definition layer and a second partition wall layer disposed on the first partition wall layer and in which a partition wall opening corresponding to the light-emitting opening is defined, depositing a preliminary cover pattern on the preliminary display panel, patterning the preliminary cover pattern so that a cover pattern disposed inside the partition wall opening is formed from the preliminary cover pattern, forming a light-emitting pattern on the anode, and forming a cathode in contact with the cover pattern on the light-emitting pattern, where the second partition wall layer protrudes from the first partition wall layer so that a lower surface of the second partition wall layer is exposed, in the depositing the preliminary cover pattern, the preliminary cover pattern is deposited to contact an exposed portion of the lower surface of the second partition wall layer, and the patterning the preliminary cover pattern is performed through a blanket etching process.

In an embodiment, the depositing the preliminary cover pattern may be performed through an atomic layer deposition (“ALD”) process.

In an embodiment, the patterning the preliminary cover pattern may be performed through a dry etching method.

In an embodiment, the partition wall opening may include a first area defined by an inner surface of the first partition wall layer and a second area defined by an inner surface of the second partition wall layer, and in the patterning the preliminary cover pattern, a portion of the preliminary cover pattern, which is disposed in the second area and the light-emitting opening and another portion of the preliminary cover pattern, which is disposed on the partition wall, may be removed, and thus the cover pattern may be disposed only in the first area.

In an embodiment, the first partition wall layer may include one of a conductive material and an insulating material, and each of the second partition wall and the cover pattern may include a conductive material.

### BRIEF DESCRIPTION OF THE DRAWINGS

The above and other embodiments, advantages and features of the disclosure will become apparent by describing in detail embodiments thereof with reference to the accompanying drawings.

FIG. 1A is a perspective view of an embodiment of a display device according to the disclosure.

FIG. 1B is an exploded perspective view of an embodiment of the display device according to the disclosure.

FIG. 2 is a cross-sectional view of an embodiment of a display panel according to the disclosure.

FIG. 3 is a plan view of an embodiment of the display panel according to the disclosure.

FIG. 4 is an enlarged plan view of an embodiment of a portion of a display area of the display panel according to the disclosure.

FIG. 5 is an enlarged cross-sectional view of an embodiment of a partial area of the display panel according to the disclosure.

FIGS. 6A and 6B are enlarged cross-sectional views of area AA′ of FIG. 5 in the display panel.

FIG. 7 is an enlarged cross-sectional view of area AA′ of FIG. 5 in the display panel.

FIG. 8 is a cross-sectional view along line I-I′ of FIG. 4 in an embodiment of the display panel according to the disclosure.

FIG. 9 is an enlarged plan view of an embodiment of a partial configuration of the display panel according to the disclosure.

FIGS. 10A to 10N are cross-sectional views illustrating an embodiment of some of operations of a method of manufacturing a display panel according to the disclosure.

FIGS. 11A to 11F are cross-sectional views illustrating an embodiment of some of operations of a method of manufacturing a display panel according to the disclosure.

### DETAILED DESCRIPTION

In the specification, the expression that a first component (or an area, a layer, a part, a portion, etc.) is “disposed on”, “connected with” or “coupled to” a second component means that the first component is directly disposed on/connected with/coupled to the second component or means that a third component is interposed therebetween.

The same reference numerals refer to the same components. Further, in the drawings, the thickness, the ratio, and the dimension of components are exaggerated for effective description of technical contents. The term “and/or” includes all combinations of one or more components that may be defined by associated components.

Although the terms “first”, “second”, etc. may be used to describe various components, the components should not be limited by the terms. The terms are only used to distinguish one component from another component. For example, without departing from the right scope of the disclosure, a first component may be also referred to as a second component, and similarly, the second component may be also referred to as the first component. Singular expressions include plural expressions unless clearly otherwise indicated in the context.

Also, the terms “under”, “below”, “on”, “above”, etc. are used to describe the correlation of components illustrated in drawings. The terms that are relative in concept are described based on a direction illustrated in drawings.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Unless otherwise defined, all terms (including technical terms and scientific terms) used in the specification have the same meaning as commonly understood by those skilled in the art to which the disclosure belongs. Furthermore, terms such as terms defined in the dictionaries commonly used should be interpreted as having a meaning consistent with the meaning in the context of the related technology and should not be interpreted in overly ideal or overly formal meanings unless explicitly defined herein.

Hereinafter, embodiments of the disclosure will be described with reference to accompanying drawings.

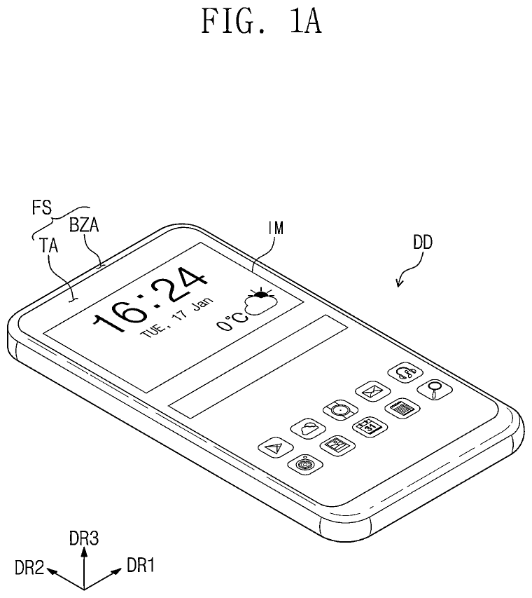

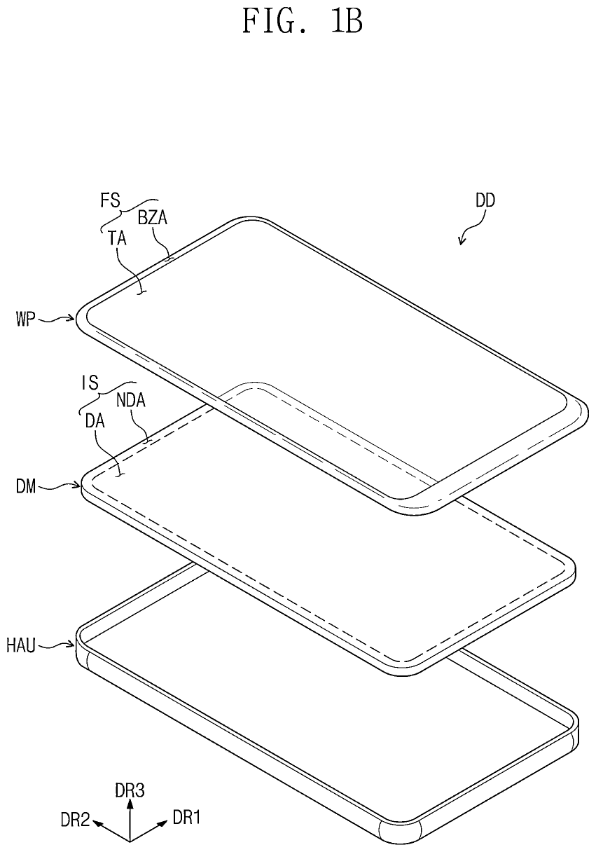

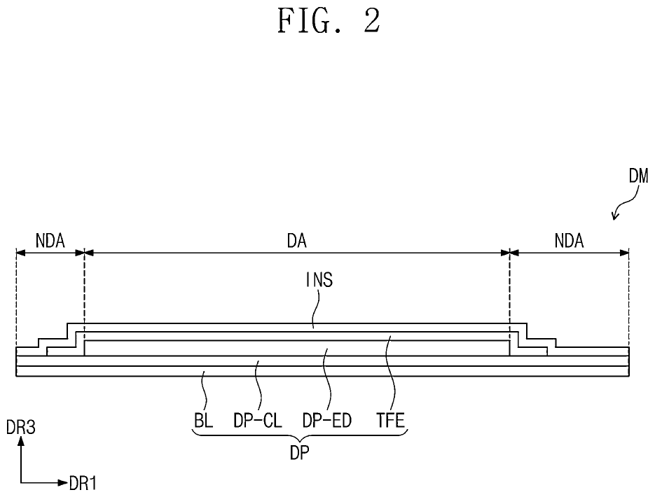

FIG. 1A is a perspective view of an embodiment of a display device according to the disclosure. FIG. 1B is an exploded perspective view of an embodiment of the display device according to the disclosure. FIG. 2 is a cross-sectional view of an embodiment of a display panel according to the disclosure.

In an embodiment, a display device DD may be a large electronic device such as a television, a monitor, or an external billboard. Further, the display device DD may be a small or medium-sized electronic device such as a personal computer (“PC”), a laptop, a personal digital terminal, a vehicle navigation unit, a game console, a smart phone, a tablet PC, and a camera. These devices are merely presented in an embodiment and may be employed as other display devices as long as the display devices do not depart from the concept of the disclosure. In an embodiment, the display device DD is illustratively illustrated as a smart phone.

Referring to FIGS. 1A, 1B, and 2, the display device DD may display an image IM in a third direction DR3 on a display surface FS parallel to a first direction DR1 and a second direction DR2. The image IM may include a still image as well as a dynamic image. In FIG. 1, a watch window and icons are illustrated in an embodiment of the image IM. The display surface FS on which the image IM is displayed may correspond to a front surface of the display device DD.

In an embodiment, a front surface (or an upper surface) and a rear surface (or a lower surface) of each member are defined with respect to a direction in which the image IM is displayed. The front surface and the rear surface may face each other in the third direction DR3, and a normal direction of each of the front and rear surfaces may be parallel to the third direction DR3. Directions indicated by the first to third directions DR1, DR2, and DR3 are relative concepts and may be changed to other directions. In the specification, a phrase of “in a plan view” may mean a state when viewed in the third direction DR3.

As illustrated in FIG. 1B, the display device DD in an embodiment may include a window WP, a display module DM, and a housing HAU. The window WP and the housing HAU may be coupled to each other to constitute an exterior of the display device DD.

The window WP may include an optically transparent insulating material. In an embodiment, the window WP may include a glass or plastic, for example. A front surface of the window WP may define the display surface FS of the display device DD. The display surface FS may include a transparent area TA and a bezel area BZA. The transparent area TA may be an optically transparent area. In an embodiment, the transparent area TA may be an area having a visible light transmittance of about 90% or more, for example.

The bezel area BZA may be an area having a relatively lower light transmittance than that of the transparent area TA. The bezel area BZA may define a shape of the transparent area TA. The bezel area BZA may be adjacent to the transparent area TA and surround the transparent area TA. This is illustratively illustrated, and in an embodiment of the window WP according to the disclosure, the bezel area BZA may be omitted. The window WP may include at least one functional layer of a fingerprint prevention layer, a hard coating layer, and a reflection prevention layer, and is not limited to a particular embodiment.

The display module DM may be disposed below the window WP. The display module DM may be a component that substantially generates the image IM. The image IM generated by the display module DM is disposed on a display surface IS of the display module DM and is visually recognized by a user from the outside through the transparent area TA.

The display module DM includes a display area DA and a non-display area NDA. The display area DA may be an area that is activated according to an electrical signal. The non-display area NDA is adjacent to the display area DA. The non-display area NDA may surround the display area DA. The non-display area NDA is an area covered by the bezel area BZA and may not be visually recognized from the outside.

As illustrated in FIG. 2, the display module DM in an embodiment may include a display panel DP and an input sensor INS. Although not separately illustrated, the display device DD in an embodiment of the disclosure may further include a protective member disposed on a lower surface of the display panel DP or a reflection prevention member and/or a window member disposed on an upper surface of the input sensor INS.

The display panel DP may be a light-emitting display panel, but the disclosure is not particularly limited thereto. In an embodiment, the display panel DP may be an organic light-emitting display panel or inorganic light-emitting display panel, for example. A light-emitting layer in the organic light-emitting display panel includes an organic light-emitting material. A light-emitting layer in the inorganic light-emitting display panel includes a quantum dot, a quantum rod, or a micro light-emitting diode (“LED”). Hereinafter, the display panel DP is described as the organic light-emitting display panel.

The display panel DP may include a base layer BL, a circuit element layer DP-CL arranged on the base layer BL, a display element layer DP-ED, and an encapsulation layer TFE. The input sensor INS may be directly disposed on the encapsulation layer TFE. In the specification, the wording “component A is directly disposed on component B” means that no adhesive layer is disposed between component A and component B.

The base layer BL may include at least one plastic film. The base layer BL is a flexible substrate and may include a plastic substrate, a glass substrate, a metal substrate, or an organic/inorganic composite material substrate. In the specification, it may be seen that the display area DA and the non-display area NDA are defined in the base layer BL, and in this case, it may be also seen that the components arranged on the base layer BL are arranged to overlap the display area DA or the non-display area NDA.

The circuit element layer DP-CL includes at least one insulating layer and a circuit element. The insulating layer includes at least one inorganic layer and at least one organic layer. The circuit element includes signal lines, a driving circuit of a pixel, or the like.

The display element layer DP-ED includes a partition wall and a light-emitting element. The light-emitting element may include an anode, a light-emitting pattern, and a cathode, and the light-emitting pattern may include at least one light-emitting layer.

The encapsulation layer TFE includes a plurality of thin films. Some thin films are arranged to improve optical efficiency, and some thin films are arranged to protect organic light-emitting diodes.

The input sensor INS acquires coordinate information of an external input. The input sensor INS may have a multilayer structure. The input sensor INS may include a single layered or multi-layered conductive layer. The input sensor INS may include a single layered or multi-layered insulating layer. The input sensor INS may detect the external input in a capacitive manner, for example. In the disclosure, an operation method of the input sensor INS is not particularly limited, and in an embodiment of the disclosure, the input sensor INS may detect the external input in an electromagnetic induction method or a pressure detection method. In an embodiment of the disclosure, the input sensor INS may be omitted.

As illustrated in FIG. 1B, the housing HAU may be coupled to the window WP. The housing HAU may be coupled to the window WP to provide a predetermined inner space. The display module DM may be accommodated in the inner space.

The housing HAU may include a material having a relatively high rigidity. In an embodiment, the housing HAU may include a plurality of frames and/or plates including a glass, a plastic, or a metal or combinations thereof, for example. The housing HAU may stably protect components of the display device DD accommodated in the inner space from an external impact.

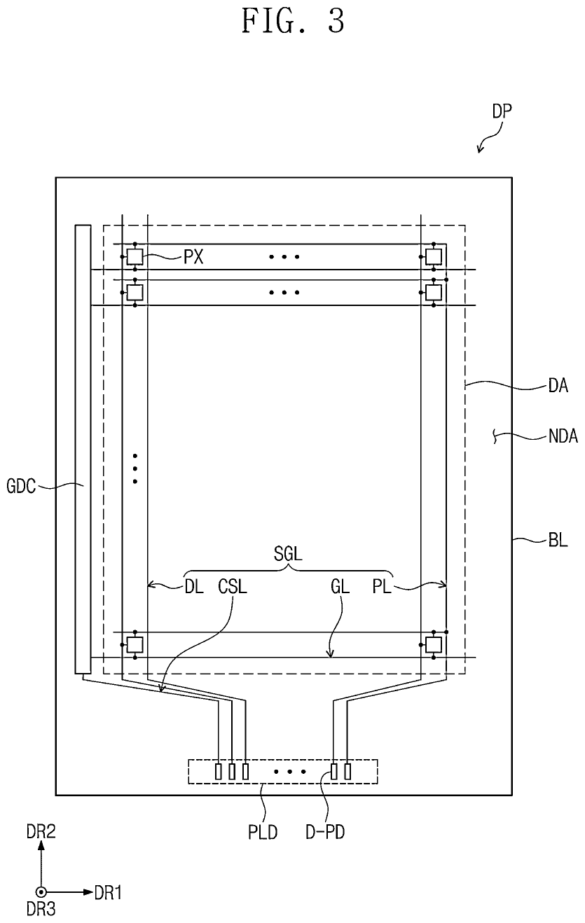

FIG. 3 is a plan view of an embodiment of the display panel according to the disclosure.

Referring to FIG. 3, the display panel DP may include the base layer BL divided into the display area DA and the non-display area NDA which have been described with reference to FIG. 2.

The display panel DP may include pixels PX arranged in the display area DA and signal lines SGL electrically connected to the pixels PX. The display panel DP may include a driving circuit GDC and a pad part PLD arranged in the non-display area NDA.

The pixels PX may be arranged in the first direction DR1 and the second direction DR2. The pixels PX may include a plurality of pixel rows extending in the first direction DR1 and arranged in the second direction DR2 and a plurality of pixel columns extending in the second direction DR2 and arranged in the first direction DR1.

The signal lines SGL may include gate lines GL, data lines DL, a power line PL, and a control signal line CSL. Each of the gate lines GL may be connected to a corresponding pixel among the pixels PX, and each of the data lines DL may be connected to a corresponding pixel among the pixels PX. The power line PL may be electrically connected to the pixels PX. The control signal line CSL may be connected to the driving circuit GDC to provide control signals to the driving circuit GDC.

The driving circuit GDC may include a gate driving circuit. The gate driving circuit may generate gate signals and sequentially output the generated gate signal to the gate lines GL. The gate driving circuit may further output another control signal to a pixel driving circuit.

The pad part PLD may be a portion to which a flexible circuit board is connected. The pad part PLD may include pixel pads D-PD, and the pixel pads D-PD may be pads for connecting the flexible circuit board to the display panel DP. Each of the pixel pads D-PD may be connected to a corresponding signal line among the signal lines SGL. The pixel pads D-PD may be connected to the corresponding pixels PX through the signal lines SGL. Further, any one pixel pad among the pixel pads D-PD may be connected to the driving circuit GDC.

Further, the pad part PLD may further include input pads. The input pads may be pads for connecting the flexible circuit board to the input sensor INS (refer to FIG. 2). However, the disclosure is not limited thereto, and the input pads may be arranged in the input sensor INS (refer to FIG. 2) and connected to the pixel pads D-PD and a separate circuit board. In an alternative embodiment, the input sensor INS (refer to FIG. 2) may be omitted and may not further include the input pads.

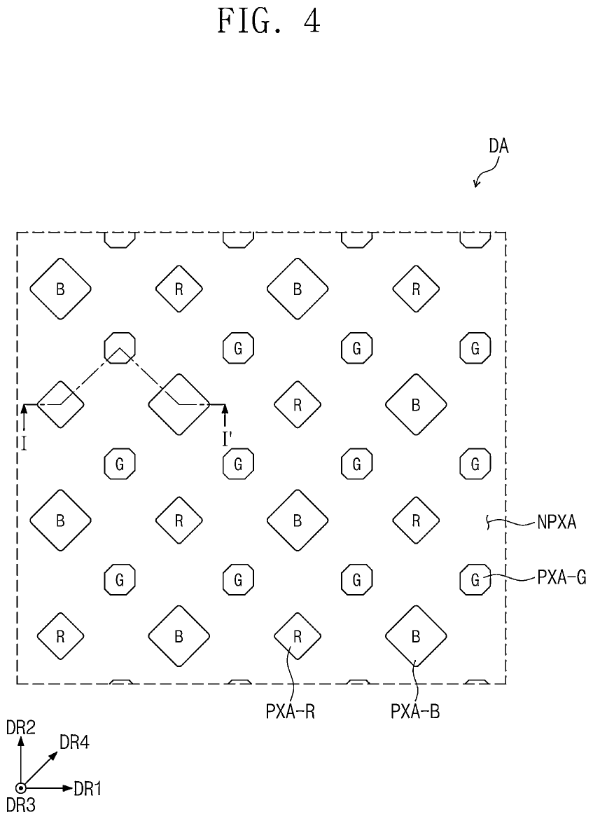

FIG. 4 is an enlarged plan view of an embodiment of a portion of a display area of the display panel according to the disclosure. FIG. 4 illustrates a flat surface of the display module DM (refer to FIG. 2) when viewed from the display surface IS (refer to FIG. 2) of the display module DM (refer to FIG. 2) and illustrates arrangement of light-emitting areas PXA-R, PXA-G, and PXA-B.

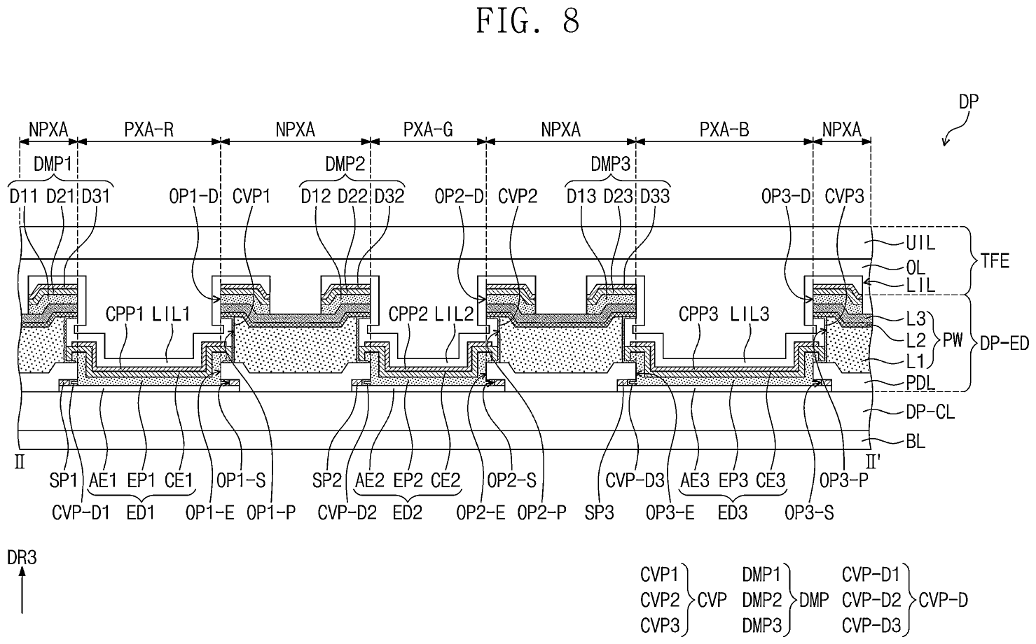

Referring to FIG. 4, the display area DA may include the first to third light-emitting areas PXA-R, PXA-G, and PXA-B and a peripheral area NPXA surrounding the first to third light-emitting areas PXA-R, PXA-G, and PXA-B. The first to third light-emitting areas PXA-R, PXA-G, and PXA-B may correspond to areas through which light beams provided from light-emitting elements ED1, ED2, and ED3 (refer to FIG. 8) are emitted, respectively. The first to third light-emitting areas PXA-R, PXA-G, and PXA-B may be classified according to a color of the light beam emitted toward the outside of the display module DM (refer to FIG. 2).

The first to third light-emitting areas PXA-R, PXA-G, and PXA-B may provide first to third color light beams having different colors, respectively. In an embodiment, the first color light beam may be a red light beam, the second color light beam may be a green light beam, and the third color light beam may be a blue color beam, for example. However, the first to third color light beams are not necessarily limited to the above example.

Each of the first to third light-emitting areas PXA-R, PXA-G, and PXA-B may be defined as an area in which an upper surface of the anode is exposed by a light-emitting opening, which will be described below. The peripheral area NPXA may set boundaries between the first to third light-emitting areas PXA-R, PXA-G, and PXA-B and prevent color mixing between the first to third light-emitting areas PXA-R, PXA-G, and PXA-B.

The first to third light-emitting areas PXA-R, PXA-G, and PXA-B may be provided in plural and may be repeatedly arranged inside the display area DA in a predetermined arrangement form. In an embodiment, the first and third light-emitting areas PXA-R and PXA-B may be alternately arranged in the first direction DR1 to constitute a “first group,” for example. The second light-emitting areas PXA-G may be arranged in the first direction DR1 to constitute a “second group.” Each of the “first group” and the “second group” may be provided in plural, and the “first groups” and the “second groups” may be alternately arranged in the second direction DR2.

One second light-emitting area PXA-G may be spaced apart from one first light-emitting area PXA-R or one third light-emitting area PXA-B in a fourth direction DR4. The fourth direction DR4 may be defined as a direction between the first and second directions DR1 and DR2.

FIG. 4 illustrates an embodiment of an arrangement form of the first to third light-emitting areas PXA-R, PXA-G, and PXA-B, but the disclosure is not limited thereto, and the first to third light-emitting areas PXA-R, PXA-G, and PXA-B may be arranged in various forms. In an embodiment, as illustrated in FIG. 4, the first to third light-emitting areas PXA-R, PXA-G, and PXA-B may have a PENTILE™ arrangement form. In an alternative embodiment, the first to third light-emitting areas PXA-R, PXA-G, and PXA-B may also have a stripe arrangement form or a Diamond Pixel™ arrangement form.

The first to third light-emitting areas PXA-R, PXA-G, and PXA-B may have various shapes in a plan view. In an embodiment, the first to third light-emitting areas PXA-R, PXA-G, and PXA-B may have shapes such as a polygonal shape, a circular shape, or an elliptic shape, for example. FIG. 4 illustratively illustrates the first and third light-emitting areas PXA-R and PXA-B having a quadrangular shape (or a diamond shape) and the second light-emitting area PXA-G having an octagonal shape in a plan view.

The first to third light-emitting areas PXA-R, PXA-G, and PXA-B may have the same shape in a plan view or may have at least partially different shapes. FIG. 4 illustratively illustrates the first and third light-emitting areas PXA-R and PXA-B having the same shape and the second light-emitting area PXA-G having a shape different from that of the first and third light-emitting areas PXA-R and PXA-B in a plan view.

At least some of the first to third light-emitting areas PXA-R, PXA-G, and PXA-B may have different areas in a plan view. In an embodiment, an area of the first light-emitting area PXA-R emitting a red light beam may be greater than an area of the second light-emitting area PXA-G emitting a green light beam and may be smaller than an area of the third light-emitting area PXA-B emitting a blue light beam. However, a size relationship between the areas of the first to third light-emitting areas PXA-R, PXA-G, and PXA-B according to the color of the emitted light beam is not limited thereto and may be varied depending on a design of the display module DM (refer to FIG. 2). Further, the disclosure is not limited thereto, and the first to third light-emitting areas PXA-R, PXA-G, and PXA-B may also have the same area in a plan view.

The shape, the area, the arrangement, or the like of the first to third light-emitting areas PXA-R, PXA-G, and PXA-B of the display module DM (refer to FIG. 2) of the disclosure may be variously designed according to the color of the emitted light beam or the size and configuration of the display module DM (refer to FIG. 2) and are not limited to an embodiment illustrated in FIG. 4.

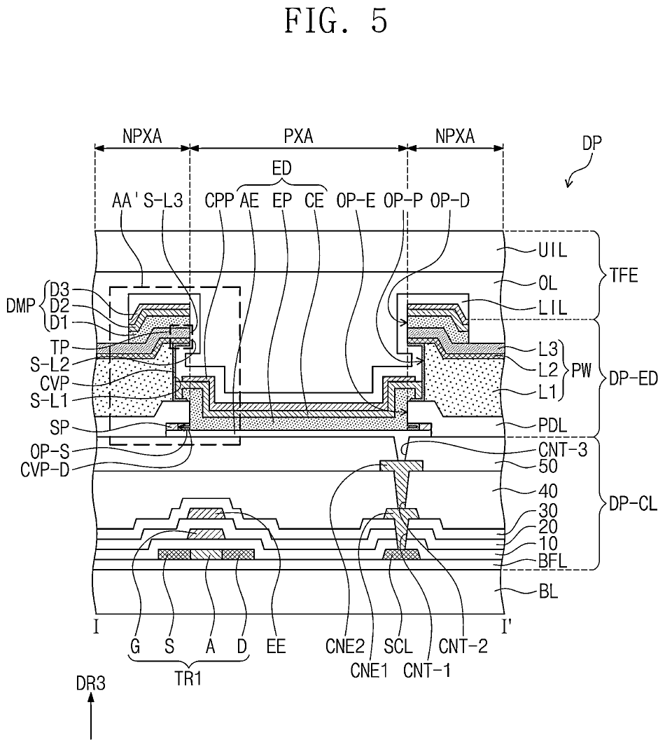

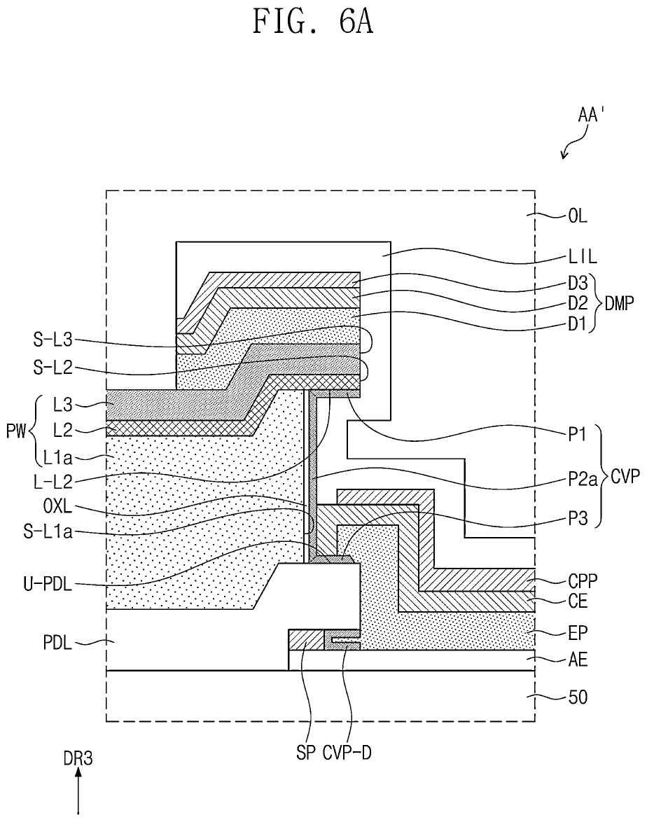

FIG. 5 is an enlarged cross-sectional view of an embodiment of a partial area of the display panel according to the disclosure. FIGS. 6A and 6B are enlarged cross-sectional views of area AA′ of FIG. 5 in the display panel.

FIG. 5 enlargedly illustrates one light-emitting area PXA in the display area DA (refer to FIG. 3), and the light-emitting area PXA of FIG. 5 may correspond to one of the first to third light-emitting areas PXA-R, PXA-G, and PXA-B of FIG. 4. Referring to FIG. 5, the display panel DP may include the base layer BL, the circuit element layer DP-CL, the display element layer DP-ED, and the encapsulation layer TFE.

The display panel DP may include a plurality of insulating layers, a semiconductor pattern, a conductive pattern, a signal line, or the like. The insulating layer, the semiconductor layer, and the conductive layer are formed by coating, deposition, or the like. Thereafter, the insulating layer, the semiconductor layer, and the conductive layer may be selectively patterned by photolithography and etching. In this manner, the semiconductor pattern, the conductive pattern, the signal line, or the like included in the circuit element layer DP-CL and the display element layer DP-ED may be formed.

The circuit element layer DP-CL may be disposed on the base layer BL. The circuit element layer DP-CL may include a buffer layer BFL, a transistor TR1, a signal transmission area SCL, first to fifth insulating layers 10, 20, 30, 40, and 50, an electrode EE, and a plurality of connection electrodes CNE1 and CNE2.

The buffer layer BFL may be disposed on the base layer BL. The buffer layer BFL may improve a coupling force between the base layer BL and the semiconductor pattern. The buffer layer BFL may include a silicon oxide layer and a silicon nitride layer. The silicon oxide layer and the silicon nitride layer may be alternately laminated.

A semiconductor pattern may be disposed on the buffer layer BFL. The semiconductor pattern may include polysilicon. However, the disclosure is not limited thereto, and the semiconductor pattern may include amorphous silicon or metal oxide. FIG. 5 merely illustrates the display portion of the semiconductor pattern, and the semiconductor patterns may be further arranged in the plurality of light-emitting areas PXA-R, PXA-G, and PXA-B (refer to FIG. 4). The semiconductor patterns may be arranged in a predetermined rule across the plurality of light-emitting areas PXA-R, PXA-G, and PXA-B (refer to FIG. 4). The semiconductor pattern may have a different electrical property depending on whether or not the semiconductor pattern is doped. The semiconductor pattern may include a first area having a relatively high doping concentration and a second area having a relatively low doping concentration. The first area may be doped with an N-type dopant or a P-type dopant. A P-type transistor may include the first area doped with the P-type dopant.

A conductivity of the first area is greater than a conductivity of the second area, and the first area may substantially serve as an electrode or a signal line. The second area may correspond to an active area (or a channel) of a transistor substantially. In other words, a portion of the semiconductor pattern may be the active area of the transistor, another portion of the semiconductor pattern may be a source area or a drain area of the transistor, and still another portion of the semiconductor pattern may be a conductive area.

A source area S, an active area A, and a drain area D of the transistor TR1 may be formed from the semiconductor pattern. FIG. 5 illustrates a portion of the signal transmission area SCL formed from the semiconductor pattern. Although not separately illustrated, the signal transmission area SCL may be connected to the drain area D of the transistor TR1 in a plan view.

The first to fifth insulating layers 10 to 50 may be arranged on the buffer layer BFL. The first to fifth insulating layers 10 to 50 may be inorganic layers or organic layers.

The first insulating layer 10 may be disposed on the buffer layer BFL. A gate G may be disposed on the first insulating layer 10. The second insulating layer 20 may be disposed on the first insulating layer 10 to cover the gate G. The electrode EE may be disposed on the second insulating layer 20. The third insulating layer 30 may be disposed on the second insulating layer 20 to cover the electrode EE.

The first connection electrode CNE1 may be disposed on the third insulating layer 30. The first connection electrode CNE1 may be connected to the signal transmission area SCL through a contact hole CNT-1 passing through the first to third insulating layers 10 to 30. The fourth insulating layer 40 may be disposed on the third insulating layer 30 to cover the first connection electrode CNE1. The fourth insulating layer 40 may be an organic layer.

The second connection electrode CNE2 may be disposed on the fourth insulating layer 40. The second connection electrode CNE2 may be connected to the first connection electrode CNE1 through a contact hole CNT-2 passing through the fourth insulating layer 40. The fifth insulating layer 50 may be disposed on the fourth insulating layer 40 to cover the second connection electrode CNE2. The fifth insulating layer 50 may be an organic layer.

The display element layer DP-ED may be disposed on the circuit element layer DP-CL. The display element layer DP-ED may include a light-emitting element ED, a pixel definition layer PDL, a partition wall PW, a cover pattern CVP, and a dummy pattern DMP.

In the disclosure, the light-emitting element ED may include an anode AE (or a first electrode), a light-emitting pattern EP, and a cathode CE (or a second electrode). Each of the first to third light-emitting elements disposed respectively corresponding to the aforementioned first to third light-emitting areas PXA-R, PXA-G, and PXA-B (refer to FIG. 4) may include substantially the same configuration as that of the light-emitting element ED of FIG. 5. The description of the anode AE, the light-emitting pattern EP, and the cathode CE may be equally applied to an anode, a light-emitting pattern, and a cathode of each of the first to third light-emitting elements.

The anode AE may be disposed on the fifth insulating layer 50 of the circuit element layer DP-CL. The anode AE may be a transmissive electrode, a semi-transmissive electrode, or a reflective electrode. The anode AE may be conductive. In an embodiment, the anode AE may include or consist of various materials such as a metal, a transparent conductive oxide (“TCO”), and a conductive polymer material as long as the materials may be conductive, for example. The anode AE may be configured as a single layer or multiple layers. In an embodiment, the anode AE may include three layers including indium tin oxide (“ITO”), silver (Ag), and indium tin oxide (“ITO”).

The anode AE may be connected to the second connection electrode CNE2 through a connection contact hole CNT-3 defined through the fifth insulating layer 50. Thus, the anode AE may be electrically connected to the signal transmission area SCL through the first and second connection electrodes CNE1 and CNE2 and thus electrically connected to the corresponding circuit element.

In an embodiment of the disclosure, the display panel DP may further include a sacrificial pattern SP. The sacrificial pattern SP may be disposed on an upper surface of the anode AE. A sacrificial opening OP-S through which a portion of the upper surface of the anode AE is exposed may be defined in the sacrificial pattern SP. The sacrificial pattern SP may include an amorphous transparent conductive oxide.

The pixel definition layer PDL may be disposed on the fifth insulating layer 50 of the circuit element layer DP-CL. A light-emitting opening OP-E may be defined by the pixel definition layer PDL. The light-emitting opening OP-E may overlap the anode AE, and the pixel definition layer PDL may expose at least a portion of the anode AE through the light-emitting opening OP-E.

Further, the light-emitting opening OP-E may correspond to the sacrificial opening OP-S of the sacrificial pattern SP. In an embodiment, the upper surface of the anode AE may be spaced apart from the pixel definition layer PDL in a cross section with the sacrificial pattern SP interposed therebetween, and accordingly, damage to the anode AE may be prevented in a process of forming the light-emitting opening OP-E.

A width of the light-emitting opening OP-E in one direction may be smaller than a width of the sacrificial opening OP-S in the one direction. In the specification, the one direction may refer to a direction perpendicular to a thickness direction (that is, the third direction DR3) of the display panel DP. That is, an inner surface of the pixel definition layer PDL defining the light-emitting opening OP-E may be closer to a center of the anode AE than an inner surface of the sacrificial pattern SP defining the sacrificial opening OP-S. However, the disclosure is not limited thereto, and the inner surface of the sacrificial pattern SP defining the sacrificial opening OP-S may be substantially aligned with the inner surface of the pixel definition layer PDL defining the corresponding light-emitting opening OP-E. In this case, the light-emitting area PXA may be regarded as an area of the anode AE exposed from the corresponding sacrificial opening OP-S. In an embodiment of the disclosure, the sacrificial pattern SP may be omitted.

The pixel definition layer PDL may include an inorganic insulating material. In an embodiment, the pixel definition layer PDL may include silicon nitride (SiNₓ), for example. The pixel definition layer PDL may be disposed between the anode AE and the partition wall PW and block electrical connection between the anode AE and the partition wall PW.

The partition wall PW may be disposed on the pixel definition layer PDL. A partition wall opening OP-P may be defined in the partition wall PW. The partition wall opening OP-P may correspond to the light-emitting opening OP-E and expose at least a portion of the anode AE.

The partition wall PW may have an undercut shape in a cross section. The partition wall PW may include a plurality of layers that are sequentially laminated, and at least one layer of the plurality of layers may be recessed as compared to adjacently stacked layers. Accordingly, the partition wall PW may include a tip portion TP.

In an embodiment, the partition wall PW may include a first partition wall layer L1, a second partition wall layer L2, and a third partition wall layer L3. The first partition wall layer L1 may be disposed on the pixel definition layer PDL, the second partition wall layer L2 may be disposed on the first partition wall layer L1, and the third partition wall layer L3 may be disposed on the second partition wall layer L2. As illustrated in FIG. 5, a thickness of the first partition wall layer L1 may be greater than thicknesses of the second and third partition wall layers L2 and L3, and the thickness of the third partition wall layer L3 may be greater than the thickness of the second partition wall layer L2 in the thickness direction (e.g., third direction DR3), but the disclosure is not limited thereto.

In an embodiment, the first partition wall layer L1 may be relatively recessed with respect to the light-emitting area PXA as compared to the second partition wall layer L2 and the third partition wall layer L3. That is, the first partition wall layer L1 may be formed by undercutting the second partition wall layer L2 and the third partition wall layer L3. A portion of the second partition wall layer L2 protruding from the first partition wall layer L1 toward the light-emitting area PXA and a portion of the third partition wall layer L3 protruding from the first partition wall layer L1 toward the light-emitting area PXA may define the tip portion TP inside the partition wall PW.

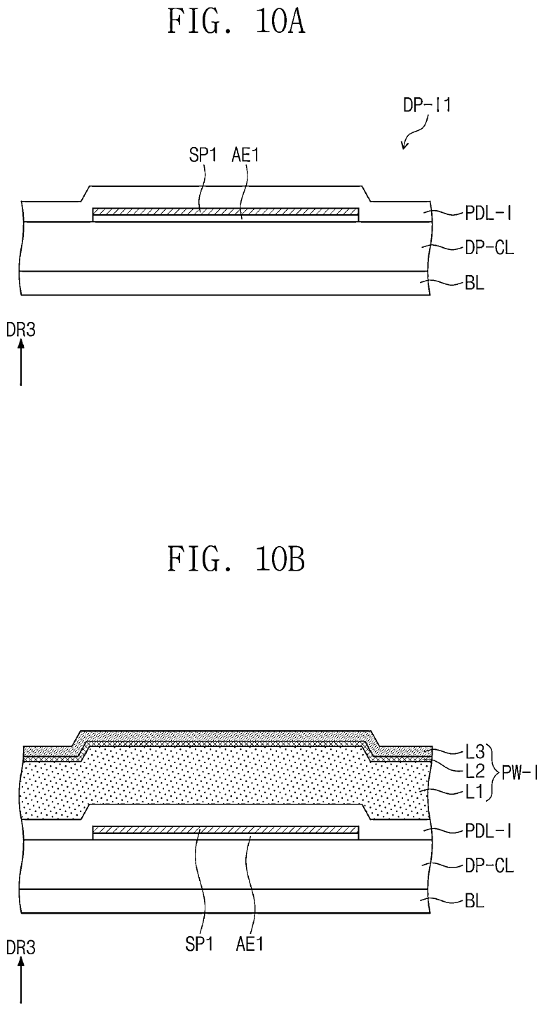

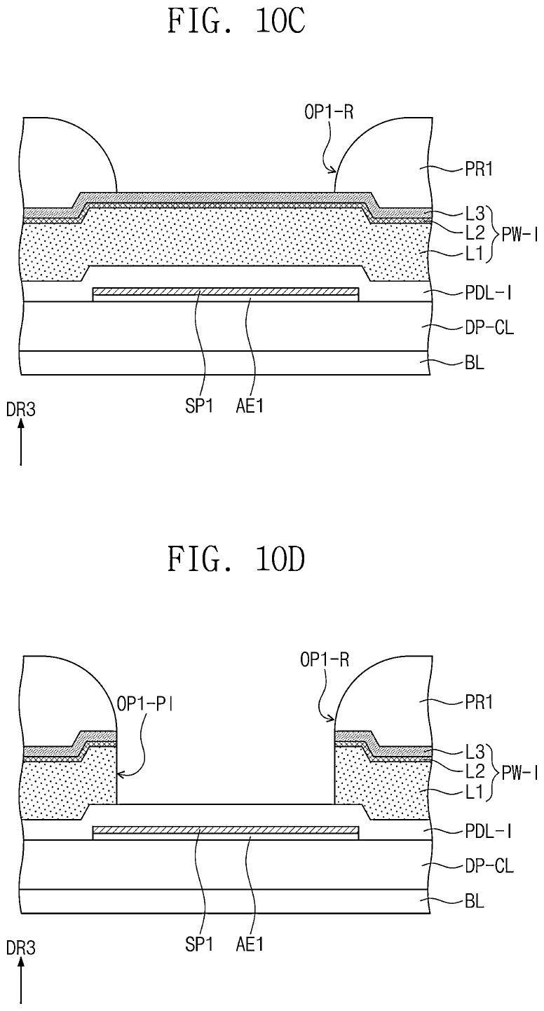

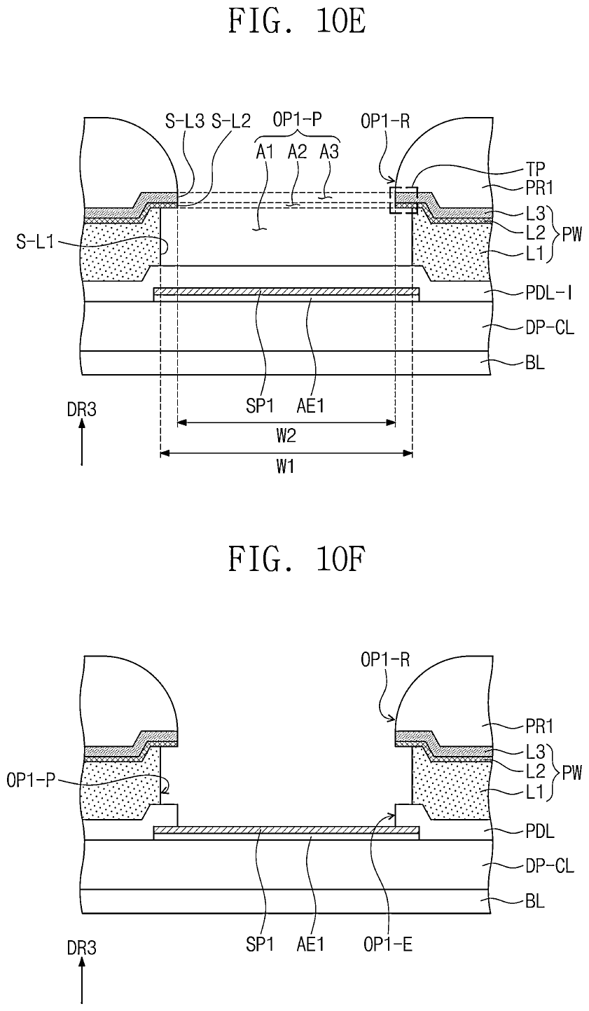

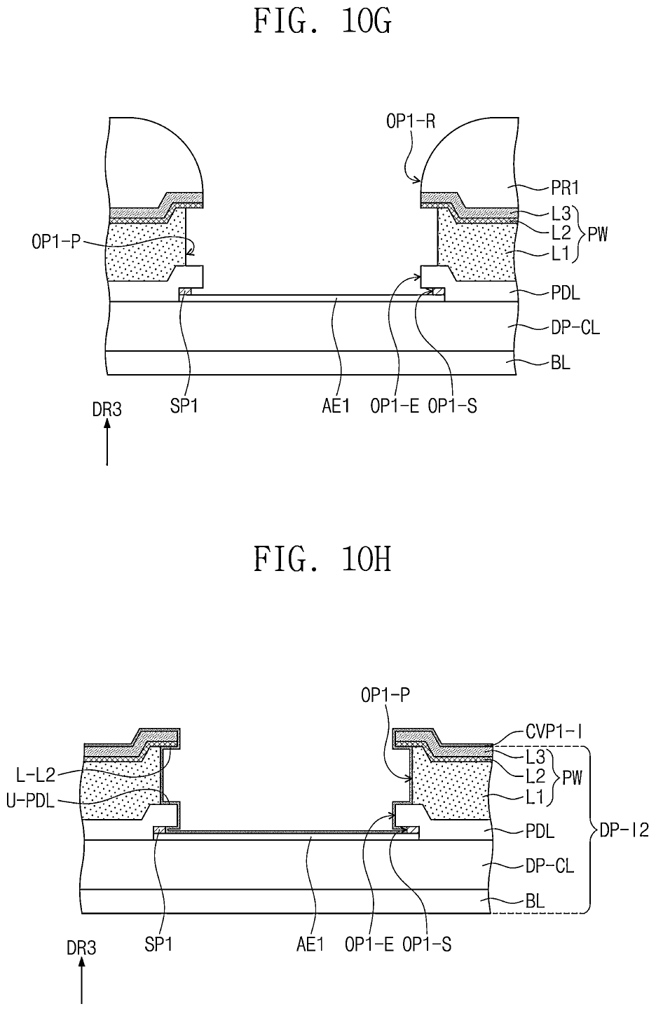

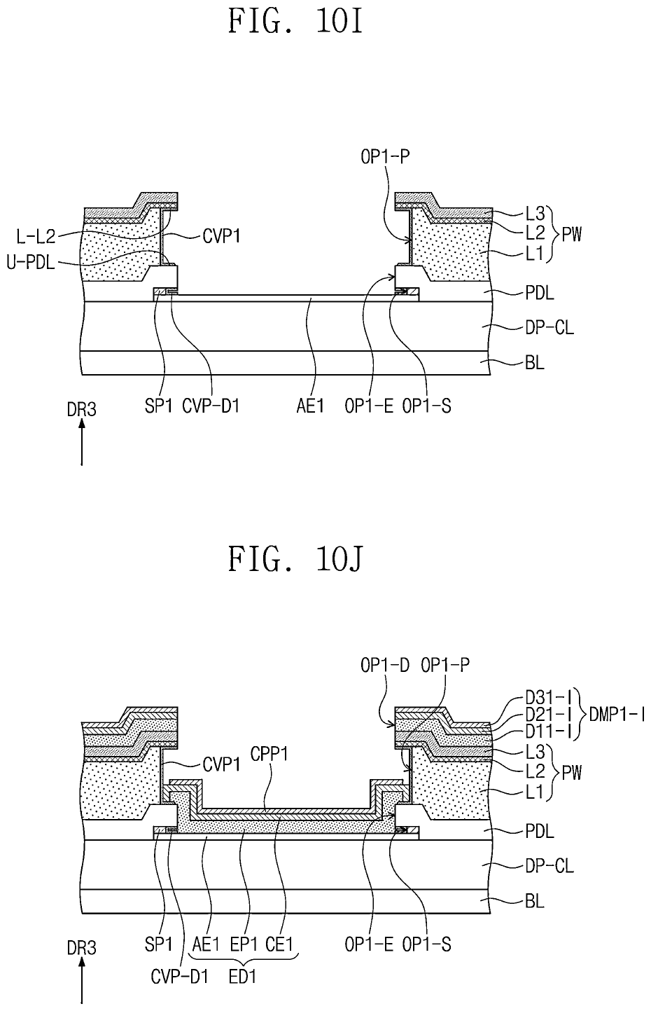

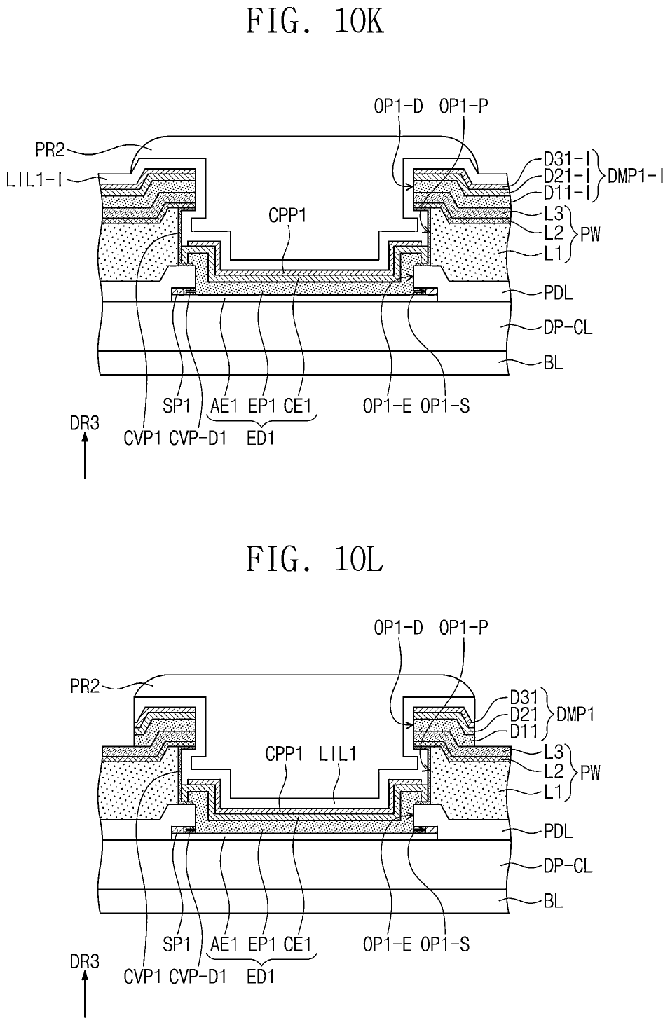

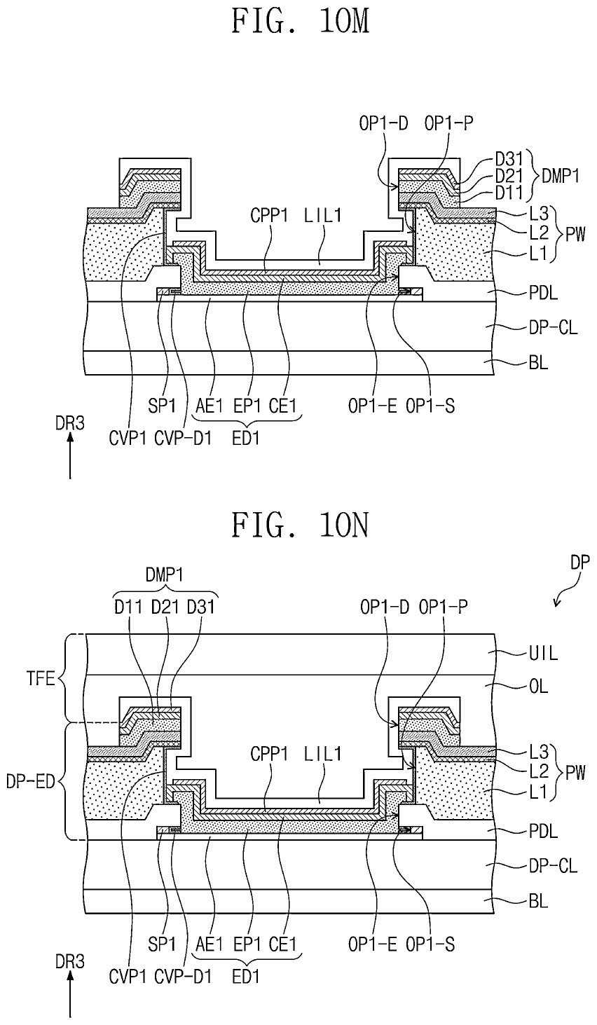

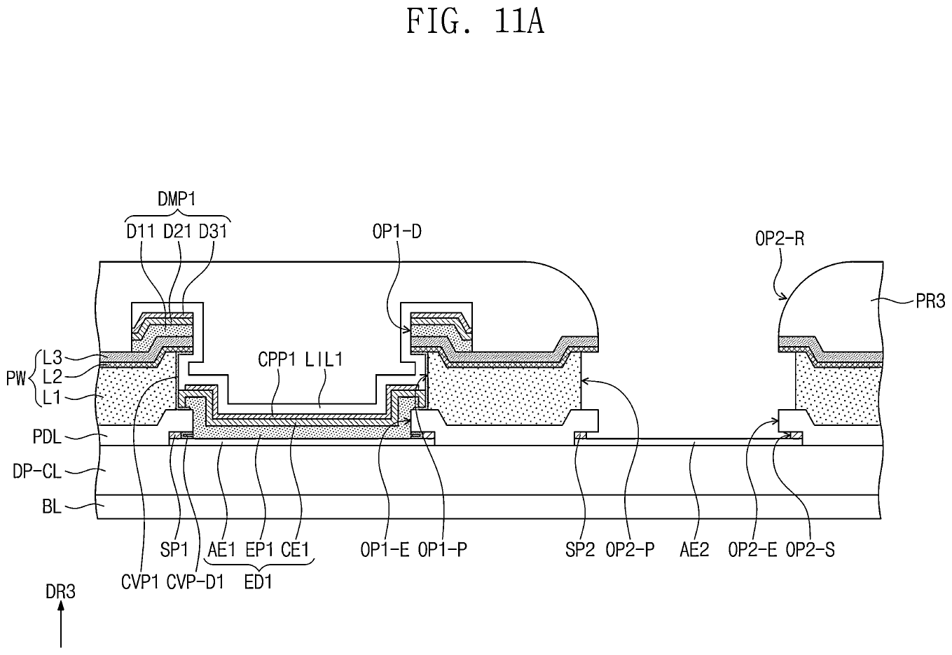

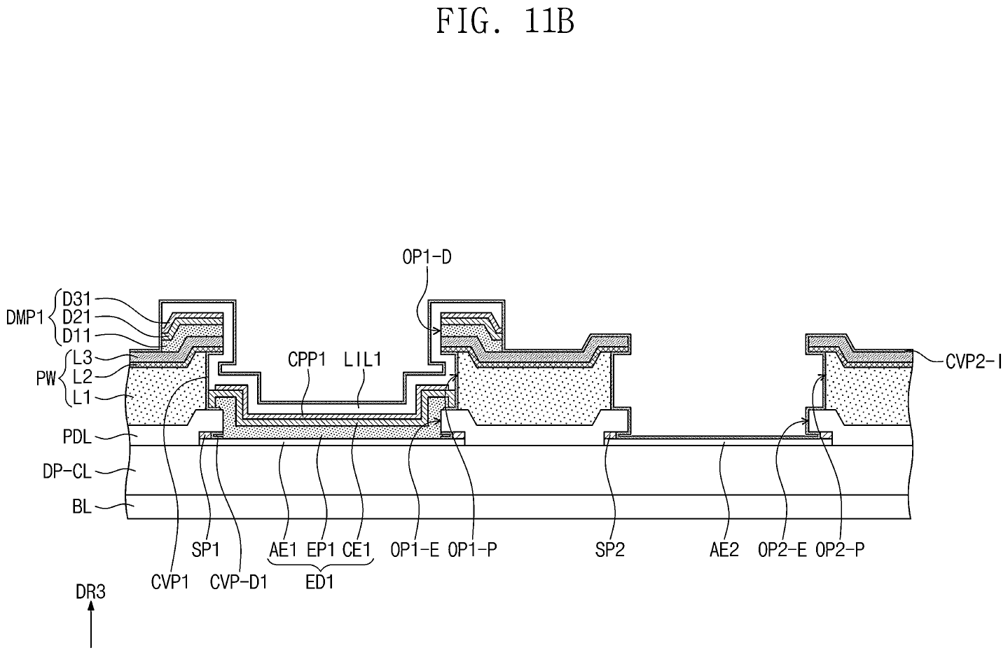

In an embodiment, the partition wall opening OP-P may include a first area A1 (refer to FIG. 10E), a second area A2 (refer to FIG. 10E), and a third area A3 (refer to FIG. 10E). The first partition wall layer L1 may include a first inner surface S-L1 defining the first area A1 of the partition wall opening OP-P. The second partition wall layer L2 may include a second inner surface S-L2 defining the second area A2 of the partition wall opening OP-P. The third partition wall layer L3 may include a third inner surface S-L3 defining the third area A3 of the partition wall opening OP-P.

In a cross section, a width W2 (refer to FIG. 10E) of the second area A2 in one direction and a width (corresponding to W2; see FIG. 10E) of the third area A3 in the one direction may be smaller than a width W1 (refer to FIG. 10E) of the first area A1 in the one direction. The second inner surface S-L2 and the third inner surface S-L3 may be closer to a center of the anode AE than the first inner surface S-L1. In other words, the first inner surface S-L1 may be recessed in a direction away from the center of the anode AE as compared to the second inner surface S-L2 and the third inner surface S-L3. Accordingly, the second partition wall layer L2 may include a lower surface L-L2 (refer to FIGS. 6A and 6B) exposed from the first partition wall layer L1.

In an embodiment of the disclosure, each of the first partition wall layer L1, the second partition wall layer L2, and the third partition wall layer L3 may include a conductive material. In an embodiment, the conductive material may include a metal, a metal nitride, a transparent conductive oxide (“TCO”), or any combinations thereof, for example. In an embodiment, the metal includes gold (Au), silver (Ag), aluminum (Al), magnesium (Mg), lithium (Li), molybdenum (Mo), titanium (Ti), copper (Cu), or alloys thereof, for example. The metal nitride may include titanium nitride (TiN). The TCO may include an indium tin oxide (“ITO”), an indium zinc oxide (“IZO”), a zinc oxide, an indium oxide, an indium gallium oxide, an indium gallium zinc oxide (“IGZO”) or an aluminum zinc oxide.

In an alternative embodiment, in another embodiment of the disclosure, the first partition wall layer L1 may include an insulating material, and each of the second partition wall layer L2 and the third partition wall layer L3 may include a conductive material. In an embodiment, the first partition wall layer L1 may include an inorganic insulating material and may include a silicon nitride (SiNₓ) or a silicon oxide (SiOₓ), for example.

In an embodiment, the second partition wall layer L2 and the third partition wall layer L3 may include different materials from each other. In this case, a modulus of the third partition wall layer L3 may be greater than a modulus of the second partition wall layer L2. Accordingly, a portion of the second partition wall layer L2 defining the tip portion TP may be prevented from being bent or cut due to components formed thereon. Therefore, the display panel DP having improved process reliability may be provided.

In an embodiment, the second partition wall layer L2 may include a titanium nitride (TiN), and the third partition wall layer L3 may include a titanium (Ti), for example. When the second partition wall layer L2 includes a titanium nitride (TiN), an oxide film may not be formed on an interface of the titanium nitride (TiN), and thus contact resistance with the cover pattern CVP may be low. Further, as a modulus of titanium (Ti) has a greater value than that of a modulus of titanium nitride (TiN), when the third partition wall layer L3 includes titanium (Ti), damage to the second partition wall layer L2 may be prevented.

As the second partition wall layer L2 has a sufficient modulus, when damage is not caused by components formed thereon, the third partition wall layer L3 may be omitted, and in this case, the third area A3 (refer to FIG. 10E) of the partition wall opening OP-P may be omitted.

FIG. 5 illustratively illustrates each of the first to third inner surfaces S-L1, S-L2, and S-L3 perpendicular to an upper surface of the fifth insulating layer 50, but the disclosure is not limited thereto, and each of the first to third partition wall layers L1, L2, and L3 may have a tapered shape or a reverse tapered shape.

The cover pattern CVP may disposed in the partition wall opening OP-P. In detail, the cover pattern CVP may be disposed only in the first area A1 (refer to FIG. 10E) defined by the first inner surface S-L1 of the partition wall opening OP-P, and may not be disposed in the second area A2 (refer to FIG. 10E) defined by the second inner surface S-L2 of the partition wall opening OP-P and the third area A3 (refer to FIG. 10E) defined by the third inner surface S-L3.

FIGS. 6A and 6B are partially enlarged cross-sectional views of the inner surfaces S-L1a, S-L1b, S-L2, and S-L3 and the cover pattern CVP defining the partition wall opening OP-P (refer to FIG. 5) of the partition wall PW.

Referring to FIG. 6A, in an embodiment, an oxide film OXL may be formed on the first inner surface S-L1a. In an embodiment, a first partition wall layer L1a may include a conductive material. A conductive material included in the first partition wall layer L1a has relatively high reactivity with oxygen, and thus an oxidation reaction may occur in an interface thereof. In an embodiment, the first partition wall layer L1a may include a metal, for example. In an embodiment, the first partition wall layer including a metal may include aluminum (Al), for example.

In an embodiment, the cover pattern CVP may include a first portion P1, a second portion P2a, and a third portion P3. The first portion P1 may be a portion in contact with the lower surface L-L2 of the second partition wall layer L2 exposed from the first partition wall layer L1a. The second portion P2a may be a portion extending from the first portion P1 and in contact with the oxide film OXL formed on the first inner surface S-L1a of the first partition wall layer L1a. The third portion P3 may be a portion extending from the second portion P2a and in contact with an upper surface U-PDL of the pixel definition layer PDL exposed from the first partition wall layer L1a.

In an embodiment, the cover pattern CVP may cover an entirety of the lower surface L-L2 of the second partition wall layer L2 exposed from the first partition wall layer L1a and the oxide film OXL formed on an entirety of the first inner surface S-L1a. The first portion P1 may cover an entirety of the lower surface L-L2 of the second partition wall layer L2 exposed from the first partition wall layer L1a. The second portion P2a may cover an entirety of the oxide film OXL formed on an entirety of the first inner surface S-L1a. That is, the second portion P2a may overlap an entirety of the first inner surface S-L1a when viewed from a direction perpendicular to the third direction DR3. The third portion P3 may cover at least a portion of the upper surface U-PDL of the pixel definition layer PDL exposed from the first partition wall layer L1a. FIG. 6A illustratively illustrates that the third portion P3 covers only a portion of the upper surface U-PDL of the pixel definition layer PDL, but the disclosure is not limited thereto, and the third portion P3 may cover an entirety of the upper surface U-PDL of the pixel definition layer PDL.

When the first partition wall layer L1a does not expose the pixel definition layer PDL, the third portion P3 may be omitted. In an embodiment, when the inner surface of the pixel definition layer PDL defining the light-emitting opening OP-E (refer to FIG. 5) is substantially aligned with the first inner surface S-L1a, the second portion P2a may also continuously extend in the third direction DR3 to cover both the inner surface of the pixel definition layer PDL defining the light-emitting opening OP-E (refer to FIG. 5) and the oxide film OXL formed on the first inner surface S-L1a, for example.

The entirety of the cover pattern CVP may overlap a portion of the second partition wall layer L2 protruding from the first partition wall layer L1a. Accordingly, the entirety of the cover pattern CVP may be covered by the second partition wall layer L2 when viewed in a plan view.

In an embodiment, the cover pattern CVP may include a conductive material. Further, the cover pattern CVP may include a material that may be formed through an atomic layer deposition (“ALD”) process, which will be described below. In an embodiment, the cover pattern CVP may include a metal or a metal nitride, the metal may be tungsten (W) or molybdenum (Mo), and the metal nitride may be titanium nitride (TiN), for example.

In an embodiment, the cover pattern CVP may be formed through the ALD process and may have a relatively small thickness of 100 angstroms (Å) or less.

Referring to FIG. 6B, in an embodiment, it is illustrated that the oxide film is not formed on the first inner surface S-L1b. In an embodiment, a first partition wall layer L1b may include an insulating material. The same/similar reference numerals are used for the same/similar components described in FIG. 6A, a duplicated description thereof will be omitted, and a difference will be mainly described.

In an embodiment, the cover pattern CVP may cover an entirety of the lower surface L-L2 of the second partition wall layer L2 exposed from the first partition wall layer L1a and the first inner surface S-L1a of the first partition wall layer L1. The cover pattern CVP may include the first portion P1, a second portion P2b, and the third portion P3, and in an embodiment, the second portion P2b may contact the first inner surface S-L1b. The second portion P2b may cover an entirety of the first inner surface S-L1b.

Referring back to FIG. 5, the light-emitting pattern EP may be disposed on the anode AE. The light-emitting pattern EP may be patterned by the tip portion TP defined by the partition wall PW. At least a portion of the light-emitting pattern EP may be disposed on the light-emitting opening OP-E. In an embodiment the entirety of the light-emitting pattern EP may be disposed inside the light-emitting opening OP-E. In an alternative embodiment, the light-emitting pattern EP may be disposed not only in the light-emitting opening OP-E but also in the partition wall opening OP-P. In an alternative embodiment including the sacrificial pattern SP, the light-emitting pattern EP may also be disposed in the sacrificial opening OP-S.

The light-emitting pattern EP may include a light-emitting layer including a light-emitting material. The light-emitting pattern EP may further include a hole injection layer (“HIL”) and a hole transport layer (“HTL”) arranged between the anode AE and the light-emitting layer and may further include an electron transport layer (“ETL”) and an electron injection layer (“EIL”) arranged on the light-emitting layer. The light-emitting pattern EP may be referred to a an “organic layer” or an “intermediate layer.”

The cathode CE may be disposed on the light-emitting pattern EP. The cathode CE may be patterned by the tip portion TP defined by the partition wall PW. At least a portion of the cathode CE may be disposed in the partition wall opening OP-P. In an embodiment of the disclosure, a portion of the cathode CE may also be disposed in the light-emitting opening OP-E according to a thickness of the light-emitting pattern EP or a thickness of the pixel definition layer PDL.

The cathode CE may be conductive. In an embodiment, the cathode CE may include or consist of various materials such as a metal, a transparent conductive oxide (“TCO”), and a conductive polymer material as long as the materials may be conductive, for example.

Referring to FIGS. 5 to 6B, the cathode CE in an embodiment may contact the cover pattern CVP. In detail, the cathode CE may contact the second portions P2a and P2b of the cover pattern CVP. In an embodiment, the cathode CE may be directly in contact with the cover pattern CVP and may be electrically connected to the partition wall PW through the cover pattern CVP.

In detail, as illustrated in FIG. 6A, when the first partition wall layer L1a includes a conductive material and the oxide film OXL is formed on the first inner surface S-L1a, the cathode CE may be electrically connected to the second partition wall layer L2 through the cover pattern CVP and may also be electrically connected to the first partition wall layer L1a and the third partition wall layer L3 through the second partition wall layer L2. That is, the cathode CE may be electrically connected to all the first to third partition wall layers L1a, L2, and L3 of the partition wall PW.

In an alternative embodiment, as in an embodiment illustrated in FIG. 6B, when the first partition wall layer L1b includes an insulating material, the cathode CE may be electrically connected to the second partition wall layer L2 through the cover pattern CVP and may also be electrically connected to the third partition wall layer L3 through the second partition wall layer L2. That is, the cathode CE may be electrically connected to the second and third partition wall layers L2 and L3 of the partition wall PW and may be insulated from the first partition wall layer L1b.

In an embodiment, the partition wall PW may receive a bias voltage. The cathode CE may be electrically connected to the partition wall PW and receive the bias voltage from the partition wall PW.

In an embodiment according to the disclosure, the cathode CE may contact the cover pattern CVP in contact with the second partition wall layer L2 and may be electrically connected to the second partition wall layer L2 through the cover pattern CVP. Accordingly, even when the cathode CE is not in contact with the first partition wall layer L1, the cathode CE may be electrically connected to the partition wall PW. That is, even when the oxide film OXL is formed on an interface of the first partition wall layer L1, this does not affect an increase in contact resistance of the cathode CE or the occurrence of failure of electric contact between the cathode CE and the partition wall PW. Accordingly, the display panel DP having improved electrical reliability may be provided by preventing the failure of the electric contact between the cathode CE and the partition wall PW.

In an embodiment, the second partition wall layer L2 may include titanium nitride (TiN), and the cover pattern CVP may include any one of tungsten (W), molybdenum (Mo), and titanium nitride (TiN). In this case, the oxide film may not be generated on an interface of each of the second partition wall layer L2 and the cover pattern CVP, and relatively low contact resistance may occur between the second partition wall layer L2 and the cover pattern CVP. Further, as the cover pattern CVP is in contact with an entirety of the lower surface L-L2 of the second partition wall layer L2 exposed from the first partition wall layer L1, a wide contact area may be secured, and thus the contact resistance between the second partition wall layer L2 and the cover pattern CVP may be reduced. In an embodiment, the cathode CE may include silver (Ag), and in this case, relatively low contact resistance may also occur between the cover pattern CVP and the cathode CE. Accordingly, an increase in a driving voltage may be prevented, and thus the display panel DP having improved display efficiency may be provided.

Unlike the disclosure, when the cathode contacts the first partition wall layer, the first partition wall layer should comprise a material that satisfies both characteristics in which a recessed undercut shape may be easily formed as compared to the second partition wall layer and characteristics in which contact resistance with the cathode is low. In an embodiment according to the disclosure, in selecting the material contained in the first partition wall layer L1, since the contact resistance with the cathode CE may not be considered, a material of which the undercut shape may be easily formed may be set relatively without limitation. Accordingly, the display panel DP having improved process ease, and at the same time, improved electrical reliability and improved display efficiency may be provided.

In an embodiment of the disclosure, the display panel DP may further include a capping pattern CPP. The capping pattern CPP may be disposed on the cathode CE. The capping pattern CPP may be patterned by the tip portion TP defined by the partition wall PW. At least a portion of the capping pattern CPP may be disposed inside the partition wall opening OP-P. FIG. 5 illustratively illustrates that the capping pattern CPP is disposed inside the partition wall opening OP-P and the light-emitting opening OP-E, but the disclosure is not limited thereto, and the capping pattern CPP may be disposed only inside the partition wall opening OP-P according to a thickness of the light-emitting pattern EP or a thickness of the pixel definition layer PDL.

The dummy pattern DMP may be disposed on the partition wall PW. The dummy pattern DMP may include a first dummy layer D1, a second dummy layer D2, and a third dummy layer D3. The first to third dummy layers D1, D2, and D3 may be sequentially stacked in the third direction DR3.

The first dummy layer D1 may include an organic material. In an embodiment, the first dummy layer D1 may include the same material as that of the light-emitting pattern EP, for example. The first dummy layer D1 may be simultaneously formed through one process together with the light-emitting pattern EP and formed separately from the light-emitting pattern EP by the undercut shape of the partition wall PW.

The second dummy layer D2 may include a conductive material. In an embodiment, the second dummy layer D2 may include the same material as that of the cathode CE, for example. The second dummy layer D2 may be simultaneously formed through one process together with the cathode CE and formed separately from the cathode CE by the undercut shape of the partition wall PW.

The third dummy layer D3 may include the same material as that of the capping pattern CPP. The third dummy layer D3 may be simultaneously formed through one process together with the capping pattern CPP and formed separately from the capping pattern CPP by the undercut shape of the partition wall PW.

A dummy opening OP-D corresponding to the light-emitting opening OP-E may be defined in the dummy pattern DMP. The dummy opening OP-D may be defined by the inner surfaces of the first to third dummy layers D1, D2, and D3. On a plane, the dummy pattern DMP may have a closed line shape extending along an outer boundary of the light-emitting area PXA.

FIG. 5 illustratively illustrates that the inner surfaces of the first to third dummy layers D1, D2, and D3 defining the dummy opening OP-D are aligned with the second inner surface S-L2 and the third inner surface S-L3, but the disclosure is not limited thereto, and the first to third dummy layers D1, D2, and D3 may cover the second inner surface S-L2 and the third inner surface S-L3.

The display panel DP in an embodiment may further include a dummy cover pattern CVP-D. When a width of the light-emitting opening OP-E in one direction is smaller than a width of the sacrificial opening OP-S in the one direction, a predetermined space in which the sacrificial pattern SP is not disposed may be formed between the anode AE and the pixel definition layer PDL. The dummy cover pattern CVP-D may be disposed in the predetermined space formed between the anode AE and the pixel definition layer PDL in the sacrificial opening OP-S. FIGS. 5 to 6B illustratively illustrate that the dummy cover pattern CVP-D is disposed in the form of a thin film along a lower surface of the pixel definition layer PDL exposed from the sacrificial pattern SP, the inner surface of the sacrificial pattern SP defining the sacrificial opening OP-S, and the upper surface of the anode AE exposed from the sacrificial pattern SP in the predetermined space formed between the anode AE and the pixel definition layer PDL. However, the disclosure is not limited thereto, and for example, the dummy cover pattern CVP-D may be disposed to completely fill the predetermined space formed between the anode AE and the pixel definition layer PDL.

The dummy cover pattern CVP-D may include the same material as that of the cover pattern CVP. The dummy cover pattern CVP-D may be simultaneously formed through one process together with the cover pattern CVP and may be separately formed through an etching process, which will be described below.

The encapsulation layer TFE may be disposed on the display element layer DP-ED. The encapsulation layer TFE may include a lower encapsulation inorganic pattern LIL, an encapsulation organic layer OL, and an upper encapsulation inorganic layer UIL.

The lower encapsulation inorganic pattern LIL may cover the light-emitting element ED. In detail, the lower encapsulation inorganic pattern LIL may cover the cathode CE, and in an embodiment, may cover the capping pattern CPP disposed on the cathode CE together.

A portion of the lower encapsulation inorganic pattern LIL may be disposed inside the light-emitting opening OP-E and the partition wall opening OP-P. The lower encapsulation inorganic pattern LIL may contact the first portion P1 and the second portions P2a and P2b of the cover pattern CVP inside the partition wall opening OP-P. The other portion of the lower encapsulation inorganic pattern LIL may be disposed on the partition wall PW. The lower encapsulation inorganic pattern LIL may contact an upper surface of the dummy pattern DMP and inner surfaces of the dummy pattern DMP defining the dummy opening OP-D.

The encapsulation organic layer OL may cover the lower encapsulation inorganic pattern LIL and provide a flat upper surface. The upper encapsulation inorganic layer UIL may be disposed on the encapsulation organic layer OL.

The lower encapsulation inorganic pattern LIL and the upper encapsulation inorganic layer UIL may protect the display element layer DP-ED from moisture/oxygen, and the encapsulation organic layer OL may protect the display element layer DP-ED from foreign substances such as dust particles.

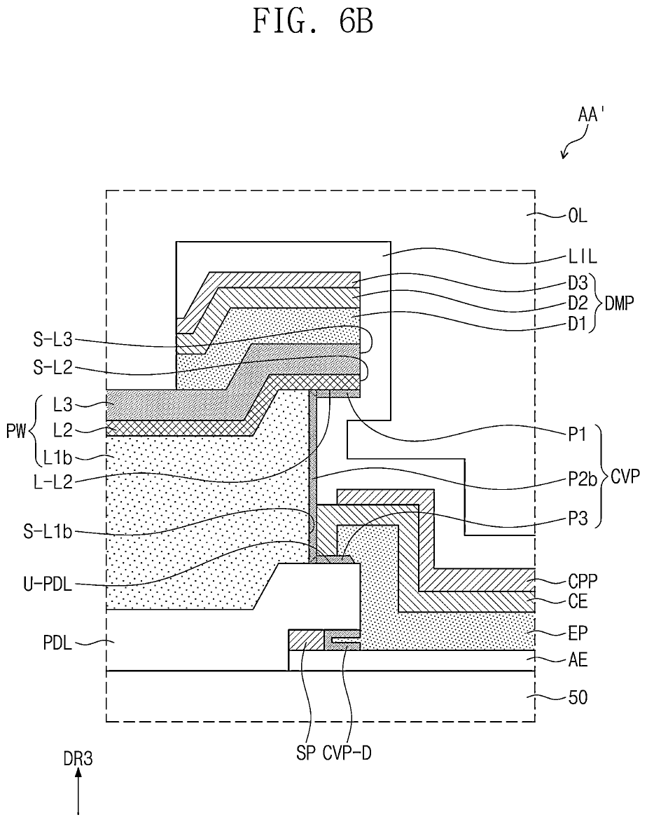

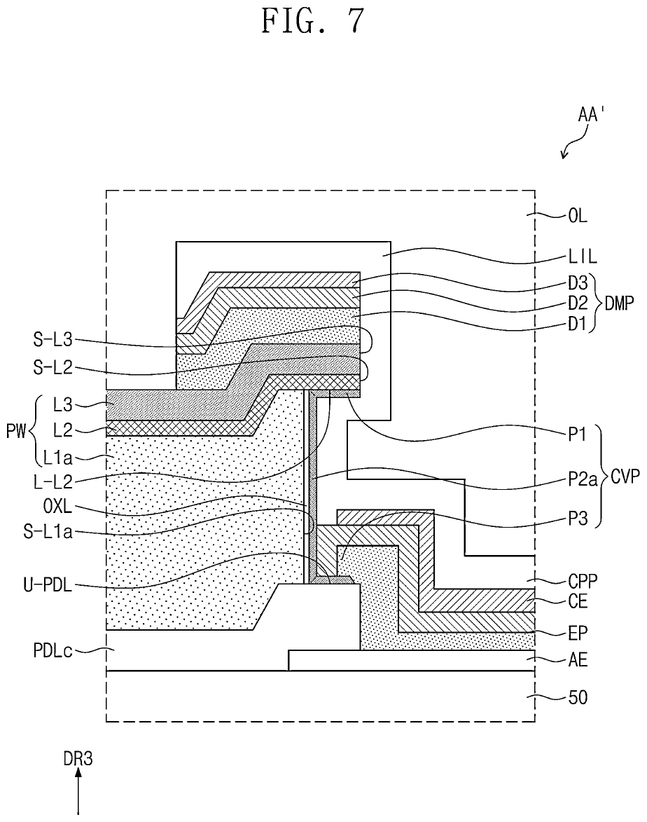

FIG. 7 is an enlarged cross-sectional view of area AA′ of FIG. 5 in an embodiment of the display panel. The same/similar reference numerals are used for the same/similar components described in FIGS. 5 to 6B, a duplicated description thereof will be omitted, and a difference will be mainly described.

Referring to FIG. 7, according to the display panel DP (refer to FIG. 5) in an embodiment, the sacrificial pattern may be omitted as compared to an embodiment described in FIGS. 5 to 6B. A pixel definition layer PDLc may contact a portion of the upper surface of the anode AE to cover the portion of the upper surface of the anode AE.

In an embodiment, as compared to an embodiment described in FIGS. 5 to 6B, a predetermined space may not be formed between the pixel definition layer PDLc and the anode AE, and accordingly, a separate dummy cover pattern spaced apart from the cover pattern CVP may not be included.

Like an embodiment described in FIG. 6A, FIG. 7 illustratively illustrates that the first partition wall layer L1a includes a conductive material and the oxide film OXL is formed in the first inner surface S-L1a. However, the disclosure is not limited thereto, and as illustrated in FIG. 6B, the first partition wall layer L1b (refer to FIG. 6B) may include an insulating material, and the oxide film may not be formed on the first inner surface S-L1b (refer to FIG. 6B).

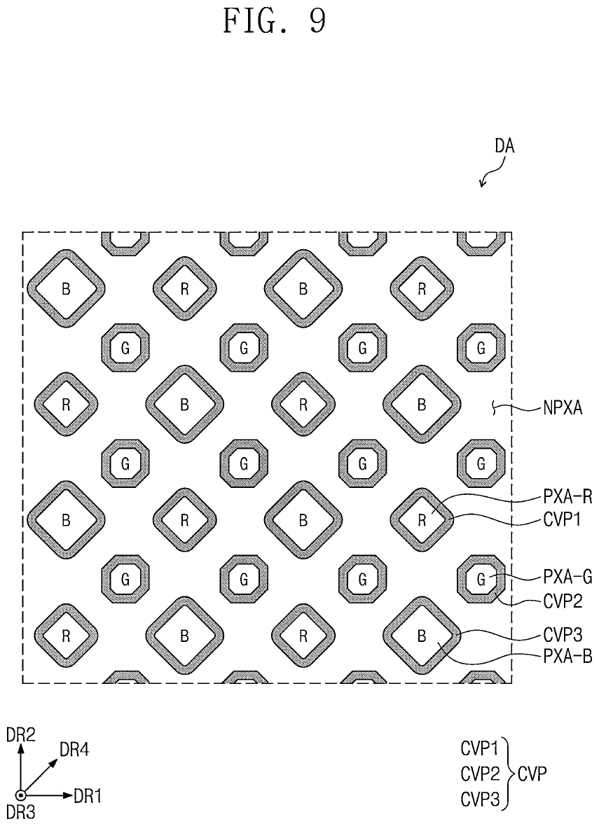

FIG. 8 is a cross-sectional view along line I-I′ of FIG. 4 in an embodiment of the display panel according to the disclosure. FIG. 9 is an enlarged plan view of an embodiment of a partial configuration of the display panel according to the disclosure.

FIG. 8 enlargedly illustrates one first light-emitting area PXA-R, one second light-emitting area PXA-G, and one third light-emitting area PXA-B, and the description of the one light-emitting area PXA of FIG. 5 may be equally applied to the first to third light-emitting areas PXA-R, PXA-G, and PXA-B.

Referring to FIG. 8, the display panel DP in an embodiment may include the base layer BL, the circuit element layer DP-CL, the display element layer DP-ED, and the encapsulation layer TFE. The display element layer DP-ED may include the light-emitting elements ED1, ED2, and ED3, the pixel definition layer PDL, the partition wall PW, the cover patterns CVP, and the dummy patterns DMP. FIG. 8 simply illustrates the circuit element layer DP-CL, and the description of the circuit element layer DP-CL of FIG. 5 may be equally applied thereto.

The light-emitting elements ED1, ED2, and ED3 may include the first light-emitting element ED1, the second light-emitting element ED2, and the third light-emitting element ED3.

The first light-emitting element ED1 may include a first anode AE1, a first light-emitting pattern EP1, and a first cathode CE1, the second light-emitting element ED2 may include a second anode AE2, a second light-emitting pattern EP2, and a second cathode CE2, and the third light-emitting element ED3 may include a third anode AE3, a third light-emitting pattern EP3, and a third cathode CE3. The first to third anodes AE1, AE2, and AE3 may be provided as a plurality of patterns. In an embodiment, the first light-emitting pattern EP1 may provide a red light beam, the second light-emitting pattern EP2 may provide a green light beam, and the third light-emitting pattern EP3 may provide a blue light beam.

First to third light-emitting openings OP1-E, OP2-E, and OP3-E may be defined in the pixel definition layer PDL.

The first light-emitting opening OP1-E may expose at least a portion of the first anode AE1. The first light-emitting area PXA-R may be defined as an area exposed by the first light-emitting opening OP1-E among an upper surface of the first anode AE1. The second light-emitting opening OP2-E may expose at least a portion of the second anode AE2. The second light-emitting area PXA-G may be defined as an area exposed by the second light-emitting opening OP2-E among an upper surface of the second anode AE2. The third light-emitting opening OP3-E may expose at least a portion of the third anode AE3. The third light-emitting area PXA-B may be defined as an area exposed by the third light-emitting opening OP3-E among an upper surface of the third anode AE3.

Sacrificial patterns SP1, SP2, and SP3 may include a first sacrificial pattern SP1, a second sacrificial pattern SP2, and a third sacrificial pattern SP3. The first to third sacrificial patterns SP1, SP2, and SP3 may be arranged on upper surfaces of the first to third anodes AE1, AE2, and AE3, respectively. First to third sacrificial openings OP1-S, OP2-S, and OP3-S corresponding to the first to third light-emitting openings OP1-E, OP2-E, and OP3-E may be defined in the first to third sacrificial patterns SP1, SP2, and SP3, respectively. In the specification, an expression “an area/part and an area/part correspond to each other” means that the area/part and the area/part overlap each other and is not limited to the same area. Thus, an expression “one opening corresponds to another opening” may mean that two openings overlap each other and is not limited to the same area.

The partition wall PW may include the first partition wall layer L1, the second partition wall layer L2, and the third partition wall layer L3. In an embodiment, first, second, and third partition wall openings OP1-P, OP2-P, and OP3-P respectively corresponding to the first, second, and third light-emitting openings OP1-E, OP2-E, and OP3-E may be defined in the partition wall PW. The partition wall opening OP-P in FIG. 5 may correspond to any one of the first, second, and third partition wall openings OP1-P, OP2-P, and OP3-P, and the description of the partition wall opening OP-P in FIG. 5 may be equally applied to the first, second, and third partition wall openings OP1-P, OP2-P, and OP3-P.

The first to third partition wall openings OP1-P, OP2-P, and OP3-P may include the first to third areas A1, A2, and A3 (refer to FIG. 10E) in FIG. 5, respectively. The first partition wall layer L1 may include the first inner surfaces S-L1 (refer to FIG. 5) defining the first areas A1 (refer to FIG. 10E) of the first to third partition wall openings OP1-P, OP2-P, and OP3-P. The second partition wall layer L2 may include the second inner surfaces S-L2 (refer to FIG. 5) defining the second areas A2 (refer to FIG. 10E) of the first to third partition wall openings OP1-P, OP2-P, and OP3-P. The third partition wall layer L3 may include the third inner surfaces S-L3 (refer to FIG. 5) defining the third areas A3 (refer to FIG. 10E) of the first to third partition wall openings OP1-P, OP2-P, and OP3-P.

The first light-emitting pattern EP1 and the first cathode CE1 may be arranged inside the first light-emitting opening OP1-E and the first partition wall opening OP1-P, the second light-emitting pattern EP2 and the second cathode CE2 may be arranged inside the second light-emitting opening OP2-E and the second partition wall opening OP2-P, and the third light-emitting pattern EP3 and the third cathode CE3 may be arranged inside the third light-emitting opening OP3-E and the third partition wall opening OP3-P.

In an embodiment according to the disclosure, the plurality of first light-emitting patterns EP1 may be patterned and deposited by the tip portion TP (refer to FIG. 5) defined in the partition wall PW in units of pixels. That is, the first light-emitting patterns EP1 may be commonly formed using an open mask but may be easily divided by the partition wall PW in units of pixels.

When the first light-emitting patterns EP1 are patterned using a fine metal mask (FMM), a support spacer protruding from the partition wall to support the FMM should be provided. Further, since the FMM is spaced apart from a base surface, on which the patterning is performed, by a height of the partition wall and the spacer, implementation in a relatively high resolution may be limited. Further, as the FMM contacts the spacer, after the patterning process for the first light-emitting patterns EP1, foreign substances may remain on the spacer, and the spacer may be damaged due to stamping of the FMM. Accordingly, a defective display panel may be formed. The description therefor may be equally applied when the second light-emitting patterns EP2 are patterned and when the third light-emitting patterns EP3 are patterned.

In an embodiment, the partition wall PW is included so that physical separation between the light-emitting elements ED1, ED2, and ED3 may be easily performed. Accordingly, current leakage or driving errors between the adjacent light-emitting areas PXA-R, PXA-G, and PXA-B may be prevented, and independent driving for each of the light-emitting elements ED1, ED2, and ED3 may be performed.

In particular, since the plurality of first light-emitting patterns EP1 are patterned without a mask in contact with an inner component inside the display area DA (refer to FIG. 2), a defect rate is reduced, and thus the display panel DP having improved process reliability may be provided. This may be equally applied when the second light-emitting patterns EP2 are patterned and when the third light-emitting patterns EP3 are patterned. As the patterning may be performed even when a separate support spacer protruding from the partition wall PW is not provided, areas of the light-emitting areas PXA-R, PXA-G, and PXA-B may be miniaturized, and thus the display panel DP that easily implements a relatively high resolution may be provided.

Further, in manufacturing the large-area display panel DP, the display panel DP may be provided in which process cost may be reduced as production of a large-area mask is omitted and process reliability may be improved as the display panel DP is not affected by defects that may occur in the large-area mask.

In an embodiment, the display panel DP may further include a first capping pattern CPP1, a second capping pattern CPP2, and a third capping pattern CPP3. The first to third capping patterns CPP1, CPP2, and CPP3 may be arranged on the first to third cathodes CE1, CE2, and CE3 and arranged inside the first to third light-emitting openings OP1-E, OP2-E, and OP3-E and the first to third partition wall openings OP1-P, OP2-P, and OP3-P, respectively.

In an embodiment, the cover patterns CVP may include a first cover pattern CVP1, a second cover pattern CVP2, and a third cover pattern CVP3. The description of the cover pattern CVP described above with reference to FIGS. 5 to 6B may be equally applied to the first to third cover patterns CVP1, CVP2, and CVP3.

The first cover pattern CVP1 may be disposed inside the first partition wall opening OP1-P, the second cover pattern CVP2 may be disposed inside the second partition wall opening OP2-P, and the third cover pattern CVP3 may be disposed inside the third partition wall opening OP3-P. In an embodiment, the first cover pattern CVP1 may be disposed only inside the first area A1 (refer to FIG. 10E) of the first partition wall opening OP1-P and may not be disposed inside the second and third areas A2 and A3 (refer to FIG. 10E) of the first partition wall opening OP1-P. The second cover pattern CVP2 may be disposed only inside the first area A1 (refer to FIG. 10E) of the second partition wall opening OP2-P and may not be disposed inside the second and third areas A2 and A3 (refer to FIG. 10E) of the second partition wall opening OP2-P. The third cover pattern CVP3 may be disposed only inside the first area A1 (refer to FIG. 10E) of the third partition wall opening OP3-P and may not be disposed inside the second and third areas A2 and A3 (refer to FIG. 10E) of the third partition wall opening OP3-P.

The first cover pattern CVP1 may contact the lower surface L-L2 (refer to FIGS. 6A and 6B) of the second partition wall layer L2 exposed from the first partition wall layer L1 in the first partition wall opening OP1-P and may be electrically connected to the second partition wall layer L2. The first cathode CE1 may contact the first cover pattern CVP1 and may be electrically connected to the second partition wall layer L2 through the first cover pattern CVP1.

The second cover pattern CVP2 may contact the lower surface L-L2 (refer to FIGS. 6A and 6B) of the second partition wall layer L2 exposed from the first partition wall layer L1 in the second partition wall opening OP2-P and may be electrically connected to the second partition wall layer L2. The second cathode CE2 may contact the second cover pattern CVP2 and may be electrically connected to the second partition wall layer L2 through the second cover pattern CVP2.

The third cover pattern CVP3 may contact the lower surface L-L2 (refer to FIGS. 6A and 6B) of the second partition wall layer L2 exposed from the first partition wall layer L1 in the third partition wall opening OP3-P and may be electrically connected to the second partition wall layer L2. The third cathode CE3 may contact the third cover pattern CVP3 and may be electrically connected to the second partition wall layer L2 through the third cover pattern CVP3.

FIG. 9 illustrates planar shapes of the first to third cover patterns CVP1, CVP2, and CVP3. For convenience of description, the first to third light-emitting areas PXA-R, PXA-G, and PXA-B are illustrated together.

Referring to FIG. 9 together, the first cover pattern CVP1, the second cover pattern CVP2, and the third cover pattern CVP3 are provided in plural, and the first cover patterns CVP1, the second cover patterns CVP2, and the third cover patterns CVP3 may be provided in the form of patterns spaced apart from each other.

On a plane, each of the first to third cover patterns CVP1, CVP2, and CVP3 may have a closed line shape. On a plane, each of the first cover patterns CVP1 may surround a corresponding first light-emitting area among the first light-emitting areas PXA-R, each of the second cover patterns CVP2 may surround a corresponding second light-emitting area among the second light-emitting areas PXA-G, and each of the third cover patterns CVP3 may surround a corresponding third light-emitting area among the third light-emitting areas PXA-B.

The first to third cathodes CE1, CE2, and CE3 may be electrically connected to the partition wall PW through the first to third cover patterns CVP1, CVP2, and CVP3, respectively. In an embodiment, the first to third cathodes CE1, CE2, and CE3 are physically separated by the tip portion TP (refer to FIG. 5) defined in the partition wall PW. However, all the first to third cathodes CE1, CE2, and CE3 may be electrically connected to the second partition wall layer L2 in the partition wall openings OP1-P, OP2-P, and OP3-P and thus receive a common voltage.

The dummy patterns DMP may include a first dummy pattern DMP1, a second dummy pattern DMP2, and a third dummy pattern DMP3. The first to third dummy patterns DMP1, DMP2, and DMP3 may be arranged on the partition wall PW.

The first dummy pattern DMP1 may include (1-1)^{th}, (2-1)^{th}, and (3-1)^{th} dummy layers D11, D21, and D31, the second dummy pattern DMP2 may include (1-2)^{th}, (2-2)^{th}, and (3-2)^{th} dummy layers D12, D22, and D32, and the third dummy pattern DMP3 may include (1-3)^{th}, (2-3)^{th}, and (3-3)^{th} dummy layers D13, D23, and D33, The description of the first dummy layer D1 of FIG. 5 may be equally applied to the (1-1)^{th} to (1-3)^{th} dummy layers D11, D12, and D13 of FIG. 6, the description of the second dummy layer D2 of FIG. 5 may be equally applied to the (2-1)^{th} to (2-3)^{th} dummy layers D21, D22, and D23 of FIG. 6, and the description of the third dummy layer D3 of FIG. 5 may be equally applied to the (3-1)^{th} to (3-3)^{th} dummy layers D31, D32, and D33 of FIG. 6.

First to third dummy openings OP1-D, OP2-D, and OP3-D corresponding to the first to third light-emitting openings OP1-E, OP2-E, and OP3-E may be defined in the first to third dummy patterns DMP1, DMP2, and DMP3, respectively. The first dummy opening OP1-D may be defined by inner surfaces of the (1-1)^{th}, (2-1)^{th}, and (3-1)^{th} dummy layers D11, D21, and D31 of the first dummy pattern DMP1. The second dummy opening OP2-D may be defined by inner surfaces of the (1-2)^{th}, (2-2)^{th}, and (3-2)^{th} dummy layers D12, D22, and D32 of the second dummy pattern DMP2. The third dummy opening OP3-D may be defined by inner surfaces of the (1-3)^{th}, (2-3)^{th}, and (3-3)^{th} dummy layers D13, D23, and D33 of the third dummy pattern DMP3.

The display panel DP in an embodiment may further include the dummy cover patterns CVP-D, and the dummy cover patterns CVP-D may include a first dummy cover pattern CVP-D1, a second dummy cover pattern CVP-D2, and a third dummy cover pattern CVP-D3. The first to third dummy cover patterns CVP-D1, CVP-D2, and CVP-D3 may be arranged between the first to third anodes AE1, AE2, AE3 and the pixel definition layer PDL inside the first to third sacrificial openings OP1-S, OP2-S, and OP3-S. The description of the dummy cover pattern CVP-D described above with reference to FIG. 5 may be equally applied to the first to third dummy cover patterns CVP-D1, CVP-D2, and CVP-D3.

The encapsulation layer TFE may include the lower encapsulation inorganic patterns LIL, the encapsulation organic layer OL, and the upper encapsulation inorganic layer UIL.

In an embodiment, the lower encapsulation inorganic patterns LIL may include a first lower encapsulation inorganic pattern LIL1, a second lower encapsulation inorganic pattern LIL2, and a third lower encapsulation inorganic pattern LIL3. The first to third lower encapsulation inorganic patterns LIL1, LIL2, and LIL3 may be provided in the form of patterns spaced apart from each other.

The first to third lower encapsulation inorganic patterns LIL1, LIL2, and LIL3 may cover the first to third light-emitting elements ED1, ED2, and ED3, respectively. In detail, the first to third lower encapsulation inorganic patterns LIL1, LIL2, and LIL3 may cover the first to third cathodes CE1, CE2, and CE3, respectively, and in an embodiment, may also cover the first to third capping patterns CPP1, CPP2, and CPP3 arranged on the first to third cathodes CE1, CE2, and CE3, respectively.

The first lower encapsulation inorganic pattern LIL1 may be provided in the form of a pattern that overlaps the first light-emitting opening OP1-E and does not overlap the second and third light-emitting openings OP2-E and OP3-E. A portion of the first lower encapsulation inorganic pattern LIL1 may be disposed inside the first light-emitting opening OP1-E and the first partition wall opening OP1-P, the other portion of the first lower encapsulation inorganic pattern LIL1 may be disposed on a portion of the partition wall PW adjacent to the first partition wall opening OP1-P, and thus the first dummy pattern DMP1 may be covered.

The second lower encapsulation inorganic pattern LIL2 may be provided in the form of a pattern that overlaps the second light-emitting opening OP2-E and does not overlap the first and third light-emitting openings OP1-E and OP3-E. A portion of the second lower encapsulation inorganic pattern LIL2 may be disposed inside the second light-emitting opening OP2-E and the second partition wall opening OP2-P, the other portion of the second lower encapsulation inorganic pattern LIL2 may be disposed on a portion of the partition wall PW adjacent to the second partition wall opening OP2-P, and thus the second dummy pattern DMP2 may be covered.

The third lower encapsulation inorganic pattern LIL3 may be provided in the form of a pattern that overlaps the third light-emitting opening OP3-E and does not overlap the first and second light-emitting openings OP1-E and OP2-E. A portion of the third lower encapsulation inorganic pattern LIL3 may be disposed inside the third light-emitting opening OP3-E and the third partition wall opening OP3-P, the other portion of the third lower encapsulation inorganic pattern LIL3 may be disposed on a portion of the partition wall PW adjacent to the third partition wall opening OP3-P, and thus the third dummy pattern DMP3 may be covered.

In an embodiment, the light-emitting patterns EP1, EP2, and EP3 are provided in the form of patterns, and the first to third lower encapsulation inorganic patterns LIL1, LIL2, and LIL3 are provided in the form of patterns covering the light-emitting elements ED1, ED2, and ED3. Therefore, formation of a moisture permeation path between adjacent light-emitting elements ED1, ED2, and ED3 may be prevented, and thus defects of the light-emitting elements ED1, ED2, and ED3 due to moisture permeation may be reduced.

FIGS. 10A to 10N are cross-sectional views illustrating an embodiment of some of operations of a method of manufacturing a display panel according to the disclosure. The same/similar reference numerals are used for the same/similar components described in FIGS. 1A to 9, and a duplicated description thereof will be omitted.

A method of manufacturing a display panel according to the disclosure includes an operation of providing a preliminary display panel including a base layer, an anode disposed on the base layer, a pixel definition layer which is disposed on the base layer and in which a light-emitting opening exposing at least a portion of the anode is defined, and a partition wall which includes a first partition wall layer disposed on the pixel definition layer and a second partition wall disposed on the first partition wall layer and in which a partition wall opening corresponding to the light-emitting opening is defined, an operation of depositing a preliminary cover pattern on the preliminary display panel, an operation of patterning the preliminary cover pattern so that a cover pattern disposed inside the partition wall opening is formed from the preliminary cover pattern, an operation of forming a light-emitting pattern on the anode, and an operation of forming a cathode in contact with the cover pattern on the light-emitting pattern. The second partition wall layer protrudes from the first partition wall layer so that a lower surface thereof is exposed, in the depositing of the preliminary cover pattern, the preliminary cover pattern is deposited in contact with the exposed lower surface of the second partition wall, and in the patterning of the preliminary cover pattern, the blanket etching process is performed.

Hereinafter, a method of forming one light-emitting element ED1 (refer to FIG. 10M) and one lower encapsulation inorganic pattern LIL1 (refer to FIG. 10M) covering the same will be described through FIGS. 10A to 10M.

FIGS. 10A to 10M illustratively illustrate a method of forming the first light-emitting element ED1 (refer to FIG. 10M) among the first to third light-emitting elements ED1, ED2, and ED3 of FIG. 8 and the first lower encapsulation inorganic pattern LIL1 (refer to FIG. 10M) among the first to third lower encapsulation inorganic patterns LIL1, LIL2, and LIL3 of FIG. 8. A formation method, which will be described below with reference to FIGS. 10A to 10M, may be similarly applied to an operation of forming the second light-emitting element ED2 (refer to FIG. 8) and the second lower encapsulation inorganic pattern LIL2 (refer to FIG. 8) and an operation of forming the third light-emitting element ED3 (refer to FIG. 8) and the third lower encapsulation inorganic pattern LIL3 (refer to FIG. 8).

Referring to FIG. 10A, the method of manufacturing a display panel in an embodiment may include an operation of providing a first preliminary display panel DP-I1. The first preliminary display panel DP-I1 provided in an embodiment may include the base layer BL, the circuit element layer DP-CL, the first anode AE1, the first sacrificial pattern SP1, and a preliminary pixel definition layer PDL-I.

The circuit element layer DP-CL may be formed by a general method of manufacturing a circuit element, in which an insulating layer, a semiconductor layer, and a conductive layer are formed through a coating method or a deposition method, the insulating layer, the semiconductor layer, and the conductive layer are selectively patterned by a photolithography and etching process, and a semiconductor pattern, a conductive pattern, a signal line or the like are formed.

The first anode AE1 and the first sacrificial pattern SP1 may be formed by the same patterning process. The preliminary pixel definition layer PDL-I may cover both the first anode AE1 and the first sacrificial pattern SP1.

Thereafter, referring to FIG. 10B, the method of manufacturing a display panel in an embodiment may include an operation of forming a preliminary partition wall PW-I including the first, second, and third partition wall layers L1, L2, and L3 on the preliminary pixel definition layer PDL-I.

The operation of forming the preliminary partition wall PW-I may include an operation of forming the first partition wall layer L1 on the preliminary pixel definition layer PDL-I, an operation of the second partition wall layer L2 on the first partition wall layer L1, and an operation of forming the third partition wall layer L3 on the second partition wall layer L2. The operation of forming the first partition wall layer L1, the operation of forming the second partition wall layer L2, and the operation of forming the third partition wall layer L3 may be performed through a deposition process.

The operation of forming the first partition wall layer L1 may be performed by a deposition process for a conductive material or a deposition process for an insulating material.

When the operation of forming the first partition wall layer L1 is performed by the deposition process for the conductive material, this operation may be performed by a sputtering deposition process. When the operation of forming the first partition wall layer L1 is performed by the deposition process for the insulating material, this operation may be performed by a chemical vapor deposition (“CVD”) process.

Each of the operation of forming the second partition wall layer L2 and the operation of forming the third partition wall layer L3 may be performed by the deposition process for the conductive material. Each of the operation of forming the second partition wall layer L2 and the operation of forming the third partition wall layer L3 may be performed by the sputtering deposition process.

In an embodiment, the preliminary partition wall PW-I in which the first partition wall layer L1 includes aluminum (Al), the second partition wall layer L2 includes titanium nitride (TiN), and the third partition wall layer L3 includes titanium (Ti) may be formed.

In an embodiment according to the disclosure, the operation of forming the third partition wall layer L3 may be omitted, and the preliminary partition wall PW-I may include only the first and second partition wall layers L1 and L2.

Thereafter, referring to FIG. 10C, the method of manufacturing a display panel in an embodiment may include an operation of forming a first photoresist layer PR1 on the preliminary partition wall PW-I. The first photoresist layer PR1 may be formed by forming a preliminary photoresist layer on the preliminary partition wall PW-I and then patterning the preliminary photoresist layer using a photo mask. Through the patterning process, a first photo opening OP1-R overlapping the first anode AE1 may be formed in the first photoresist layer PR1.

Thereafter, referring to FIGS. 10D and 10E, the method of manufacturing a display panel in an embodiment may include an operation of patterning the first to third partition wall layers L1, L2, and L3 so that the partition wall PW is formed from the preliminary partition wall PW-I. In an embodiment, the operation of patterning the first to third partition wall layers L1, L2, and L3 may be performed by two etching processes.

First, as illustrated in FIG. 10D, the operation of patterning the first to third partition wall layers L1, L2, and L3 may include an operation of firstly etching the first to third partition wall layers L1, L2, and L3. In the firstly etching operation, the first photoresist layer PR1 may be used as a mask, and a first preliminary partition wall opening OP1-PI may be defined in the preliminary partition wall PW-I. The firstly etching operation may be performed by a dry etching process.

The firstly etching operation in an embodiment may be performed under an etching environment in which the etching selectivity between the first to third partition wall layers L1, L2, and L3 is substantially the same. Accordingly, inner surfaces of the first to third partition wall layers L1, L2, and L3 defining the first preliminary partition wall opening OP1-PI may be substantially aligned with each other.

Thereafter, as illustrated in FIG. 10E, the operation of patterning the first to third partition wall layers L1, L2, and L3 may include an operation of secondly etching the first to third partition wall layers L1, L2, and L3. In the secondly etching operation, the first photoresist layer PR1 may be used as a mask, and the first partition wall opening OP1-P may be defined in the first preliminary partition wall opening OP1-PI. The secondly etching operation may be performed by a wet etching process.

The secondly etching operation in an embodiment may be performed under an environment in which the etching selectivity between the first partition wall layer L1 and the second and third partition wall layers L2 and L3 is large. Accordingly, an inner surface of the partition wall PW defining the first partition wall opening OP1-P may have an undercut shape in a cross section.

In detail, with respect to an etching solution in the secondly etching operation, an etching rate of the first partition wall layer L1 is greater than etching rates of the second and third partition wall layers L2 and L3, and thus the first partition wall layer L1 may be mainly etched. In this case, according to a condition of the secondly etching operation, the second partition wall layer L2 or the third partition wall layer L3 may be partially etched together with the first partition wall layer L1. In an alternative embodiment, according to a condition of the secondly etching operation, the second partition wall layer L2 or the third partition wall layer L3 may not be etched. When the second and third partition wall layers L2 and L3 are not etched, it may be considered that, in the operation of patterning the preliminary partition wall PW-I, after the operation of firstly etching the first to third partition wall layers L1, L2, and L3, an operation of secondly etching only the first partition wall layer L1 is performed.

The first partition wall opening OP1-P may include the first area A1, the second area A2, and the third area A3 sequentially arranged in the thickness direction (that is, the third direction DR3). The first partition wall layer L1 may include the first inner surface S-L1 defining the first area A1 of the first partition wall opening OP1-P. The second partition wall layer L2 may include the second inner surface S-L2 defining the second area A2 of the second partition wall opening OP2-P. The third partition wall layer L3 may include the third inner surface S-L3 defining the third area A3 of the third partition wall opening OP3-P.

Through the secondly etching operation, the first inner surface S-L1 may be further recessed in a direction away from a center of the first anode AE1 as compared to the second and third inner surfaces S-L2 and S-L3. The tip portion TP may be formed in the partition wall PW by the portion of the second partition wall layer L2 protruding from the first partition wall layer L1.

Further, in a cross section, each of the width W2 of the second area A2 in the one direction and the width (corresponding to W2) of the third area A3 in the one direction may be smaller than the width W1 of the first area A1 in the one direction.

An etching method of forming the partition wall PW from the preliminary partition wall PW-I is not limited to a particular embodiment, and various etching methods may be adopted according to materials of the first to third partition wall layers L1, L2, and L3.

Thereafter, referring to FIGS. 10E an 10F, the method of manufacturing a display panel in an embodiment may include an operation of thirdly etching the preliminary pixel definition layer PDL-I so that the pixel definition layer PDL is formed. The thirdly etching operation may be performed by a dry etching method and may be performed using the first photoresist layer PR1 and the second and third partition wall layers L2 and L3 as masks. The first light-emitting opening OP1-E corresponding to the first partition wall opening OP1-P may be defined in the pixel definition layer PDL.

Thereafter, referring to FIGS. 10F and 10G, the method of manufacturing a display panel in an embodiment may include an operation of fourthly etching the first sacrificial pattern SP1. The fourthly etching operation may be performed by a wet etching method and may be performed using the first photoresist layer PR1 and the second and third partition wall layers L2 and L3 as masks.

The first sacrificial opening OP1-S corresponding to the first light-emitting opening OP1-E may be defined in the first sacrificial pattern SP1. At least a portion of the first anode AE1 may be exposed from the first sacrificial pattern SP1 and the pixel definition layer PDL by the first sacrificial opening OP1-S and the first light-emitting opening OP1-E.

The etching process for the first sacrificial pattern SP1 may be performed in an environment in which an etching selectivity ratio between the first sacrificial pattern SP1 and the first anode AE1 is large, and therefore, the first anode AE1 may be prevented from being etched together. That is, as the first sacrificial pattern SP1 having a higher etching rate than that of the first anode AE1 is disposed between the pixel definition layer PDL and the first anode AE1, the first anode AE1 may be prevented from being etched together and damaged during the etching process.

Thereafter referring to FIGS. 10G and 10H, a second group process in an embodiment may include an operation of removing the first photoresist layer PR1. In the specification, after the operation of removing the first photoresist layer PR1, it is considered that a second preliminary display panel DP-I2 (preliminary display panel in claims) is provided. That is, the second preliminary display panel DP-I2 may include the base layer BL, the circuit element layer DP-CL, the first anode AE1, the pixel definition layer PDL in which the first light-emitting opening OP1-E is defined, and the partition wall PW in which the first partition wall opening OP1-P is defined.

Thereafter, referring to FIG. 10H, the method of manufacturing a display panel in an embodiment may include an operation of forming a first preliminary cover pattern CVP1-I on the second preliminary display panel DP-I2.

In an embodiment, the first preliminary cover pattern CVP1-I may be formed through a deposition process for a conductive material. The conductive material deposited in the operation of forming the first preliminary cover pattern CVP1-I may include a metal or a metal nitride, the metal may be tungsten (W) or molybdenum (Mo), and the metal nitride may be titanium nitride (TN).

In an embodiment, the operation of forming the first preliminary cover pattern CVP1-I may be performed through the ALD process. Since a deposited layer having substantially excellent step coverage may be formed through the ALD process, the first preliminary cover pattern CVP1-I may be formed to cover all exposed surfaces.

In detail, the first preliminary cover pattern CVP1-I may cover all the first to third inner surfaces S-L1, S-L2, and S-L3 (refer to FIG. 10E) inside the first partition wall opening OP1-P, the lower surface L-L2 of the second partition wall layer L2 exposed from the first partition wall layer L1, and the upper surface U-PDL of the pixel definition layer PDL exposed from the first partition wall layer L1. Further, the first preliminary cover pattern CVP1-I may cover an entirety of an inner surface of the pixel definition layer PDL defining the first light-emitting opening OP1-E and may cover an entirety of the lower surface of the pixel definition layer PDL exposed from the first sacrificial pattern SP1 and the upper surface of the first anode AE1 exposed from the first sacrificial pattern SP1 in the first sacrificial opening OP1-S. Further, the first preliminary cover pattern CVP1-I may cover an entirety of an upper surface of the partition wall PW.

In an embodiment, the first preliminary cover pattern CVP1-I may be formed through the ALD process and may be formed to have a relatively small thickness of 100 Å or less.

Referring to FIGS. 10H and 10I, the method of manufacturing a display panel in an embodiment may include an operation of patterning the first preliminary cover pattern CVP1-I so that the first cover pattern CVP1 is formed from the first preliminary cover pattern CVP1-I.

The operation of patterning the first preliminary cover pattern CVP1-I may include an operation of fifthly etching the first preliminary cover pattern CVP1-I. The fifthly etching operation may be performed through the blanket etching process. That is, the operation of patterning the first preliminary cover pattern CVP1-I may be performed without a separate process of forming a photoresist layer.

Accordingly, a portion disposed inside the second and third areas A2 and A3 (refer to FIG. 10E) of the first partition wall opening OP1-P, a portion disposed inside the first light-emitting opening OP1-E, a portion disposed on the first anode AE1 exposed by the first light-emitting opening OP1-E, and a portion disposed on the partition wall PW among the first preliminary cover pattern CVP1-I may be removed.

A portion of the first preliminary cover pattern CVP1-I, which is disposed in the first area A1 (refer to FIG. 10E) of the first partition wall opening OP1-P, may remain due to the undercut shape in the partition wall PW so that the first cover pattern CVP1 may be formed. Further, a portion of the first preliminary cover pattern CVP1-I, which is disposed inside the first sacrificial opening OP1-S, remains due to the undercut shape formed by the pixel definition layer PDL and the first sacrificial pattern SP1 so that the first dummy cover pattern CVP-D1 may be formed. That is, through etching the first preliminary cover pattern CVP1-I, the first cover pattern CVP1 and the first dummy cover pattern CVP-D1 may be formed from the first preliminary cover pattern CVP1-I.

The first cover pattern CVP1 may cover both the lower surface L-L2 of the second partition wall layer L2 exposed from the first partition wall layer L1 and the first inner surface S-L1 (refer to FIG. 10E) defining the first area A1 (refer to FIG. 10E) of the first partition wall opening OP1-P inside the first partition wall opening OP1-P and may cover at least a portion of the upper surface U-PDL of the pixel definition layer PDL exposed from the first partition wall layer L1.

In an embodiment, the fifthly etching operation may be performed by a dry etching process. The dry etching process is performed as an anisotropic process, and a portion of the first preliminary cover pattern CVP1-I, which contacts the lower surface L-L2 of the second partition wall layer L2 exposed from the first partition wall layer L1, may not be removed during the etching process. Accordingly, a reduction in a contact area between the first cover pattern CVP1 and the second partition wall layer L2 may be prevented.

Thereafter, referring to FIG. 10J, the method of manufacturing a display panel in an embodiment may include an operation of forming the first light-emitting pattern EP1, an operation of forming the first cathode CE1, and an operation of forming the first capping pattern CPP1.

The operation of forming the first light-emitting pattern EP1, the operation of forming the first cathode CE1, and the operation of forming the first capping pattern CPP1 may be performed by a deposition process. In an embodiment, the operation of forming the first light-emitting pattern EP1 may be performed by a thermal evaporation process, the operation of forming the first cathode CE1 may be performed by a sputtering process, and the operation of forming the first capping pattern CPP1 may be performed by the thermal evaporation process. However, the disclosure is not limited thereto.

In the operation of forming the first light-emitting pattern EP1, the first light-emitting pattern EP1 may be separated by the tip portion TP (refer to FIG. 10E) formed in the partition wall PW and thus may be disposed inside the first light-emitting opening OP1-E and the first partition wall opening OP1-P.

In the operation of forming the first light-emitting pattern EP1, a (1-1)^{th} preliminary dummy layer D11-I spaced apart from the first light-emitting pattern EP1 may be formed on the partition wall PW together.

In the operation of forming the first cathode CE1, the first cathode CE1 may be separated by the tip portion TP (refer to FIG. 10E) inside the partition wall PW and thus may be disposed inside the first light-emitting opening OP1-E and the first partition wall opening OP1-P. The first cathode CE1 may be provided at a higher incident angle than that of the first light-emitting pattern EP1, and the first cathode CE1 may be formed to contact the first cover pattern CVP1. In an embodiment, the first cathode CE1 may be electrically connected to the partition wall PW through the first cover pattern CVP1 in contact with the second partition wall layer L2.

The first anode AE1, the first light-emitting pattern EP1, and the first cathode CE1 may constitute the first light-emitting element ED1.

In the operation of forming the first cathode CE1, a (2-1)^{th} preliminary dummy layer D21-I spaced apart from the first cathode CE1 may be formed on the partition wall PW together.

In the operation of forming the first capping pattern CPP1, the first capping pattern CPP1 may be separated by the tip portion TP (refer to FIG. 10E) inside the partition wall PW and thus may be disposed inside the first light-emitting opening OP1-E and the first partition wall opening OP1-P.

In the operation of forming the first capping pattern CPP1, a (3-1)^{th} preliminary dummy layer D31-I spaced apart from the first capping pattern CPP1 may be formed on the partition wall PW together. In an embodiment according to the disclosure, the forming of the first capping pattern CPP1 may be omitted.

The (1-1)^{th} to (3-1)^{th} preliminary dummy layers D11-I, D21-I, and D31-I may form a first preliminary dummy pattern DMP1-I, and the first dummy opening OP1-D may be formed in the first preliminary dummy pattern DMP1-I. The first dummy opening OP1-D may be defined by inner surfaces of the (1-1)^{th} to (3-1)^{th} preliminary dummy layers D11-I, D21-I, and D31-I.

Thereafter, referring to FIG. 10K, the method of manufacturing a display panel in an embodiment may include an operation of forming a first preliminary lower encapsulation inorganic pattern LIL1-I.

The first preliminary lower encapsulation inorganic pattern LIL1-I may be formed through a deposition process. In an embodiment, the first preliminary lower encapsulation inorganic pattern LIL1-I may include an inorganic material, and may include a silicon nitride (SiNₓ), for example. In an embodiment, the first preliminary lower encapsulation inorganic pattern LIL1-I may be formed through the CVD process, for example.

The first preliminary lower encapsulation inorganic pattern LIL1-I may cover the first light-emitting element ED1. A portion of the first preliminary lower encapsulation inorganic pattern LIL1-I may be disposed inside the first partition wall opening OP1-P. The other portion of the first preliminary lower encapsulation inorganic pattern LIL1-I may cover the first preliminary dummy pattern DMP1-I on the partition wall PW.

Thereafter, the method of manufacturing a display panel in an embodiment may include an operation of forming a second photoresist layer PR2.

In the operation of forming the second photoresist layer PR2, the second photoresist layer PR2 may be formed by forming a preliminary photoresist layer, and then patterning the preliminary photoresist layer using a photo mask. Through the patterning process, the second photoresist layer PR2 may be formed in a pattern overlapping the first anode AE1 and the first light-emitting opening OP1-E. In this case, the second photoresist layer PR2 may be formed so as not to overlap the second and third anodes AE2 and AE3 (refer to FIG. 8).

Thereafter, referring to FIGS. 10K and 10L, the method of manufacturing a display panel in an embodiment may include an operation of patterning the first preliminary lower encapsulation inorganic pattern LIL1-I to form the first lower encapsulation inorganic pattern LIL1 and an operation of patterning the first preliminary dummy pattern DMP1-I to form the first dummy pattern DMP1.

The operation of patterning the first preliminary lower encapsulation inorganic pattern LIL1-I may include an operation of sixthly etching the first preliminary lower encapsulation inorganic pattern LIL1-I. The sixthly etching operation may be performed by a dry etching method and may be performed using the second photoresist layer PR2 as a mask.

A portion of the first preliminary lower encapsulation inorganic pattern LIL1-I overlapping other anodes except for the corresponding anode may be removed. In detail, when the first preliminary lower encapsulation inorganic pattern LIL1-I is formed to form the first lower encapsulation inorganic pattern LIL1 covering the first light-emitting element ED1, it may be considered that the first preliminary lower encapsulation inorganic pattern LIL1-I corresponds to the first anode AE1 included in the first light-emitting element ED1 and may be patterned so that a portion of the first preliminary lower encapsulation inorganic pattern LIL1-I overlapping the second and third anodes AE2 and AE3 (refer to FIG. 8) is removed.

Therefore, the first lower encapsulation inorganic pattern LIL1 may be formed in the form of a pattern overlapping the first anode AE1 and not overlapping the second and third anodes AE2 and AE3 (refer to FIG. 8). A portion of the first lower encapsulation inorganic pattern LIL1 may be disposed inside the first partition wall opening OP1-P to cover the first light-emitting element ED1, and the other portion of the first lower encapsulation inorganic pattern LIL1 may be disposed on the partition wall PW.

The operation of patterning the first preliminary dummy pattern DMP1-I may include an operation of seventhly etching the (1-1)^{th} to (3-1)^{th} preliminary dummy layers D11-I, D21-I and D31-I. The seventhly etching operation may be performed by a dry etching method and may be performed using the second photoresist layer PR2 as a mask.

Portions of the (1-1)^{th} to (3-1)^{th} preliminary dummy layers D11-I, D21-I, and D31-I overlapping other anodes except for the corresponding anode may be removed. In detail, when the first preliminary dummy pattern DMP1-I is simultaneously formed in a process of forming the first light-emitting pattern EP1 and the first cathode CE1 included in the first light-emitting element ED1, it may be considered the first preliminary dummy pattern DMP1-I may correspond to the first anode AE1 included in the light-emitting element ED1 and may be patterned so that a portion thereof overlapping the second and third anodes AE2 and AE3 (refer to FIG. 8) may be removed.

Therefore, the first dummy opening OP1-D overlapping the first anode AE1 may be defined, and the first dummy pattern DMP1 may be formed in the form of a pattern not overlapping the second and third anodes AE2 and AE3. The first dummy pattern DMP1 may have a closed-line shape surrounding the corresponding light-emitting area (i.e., the first light-emitting area PXA-R; see FIG. 9) in a plan view.

Thereafter, referring to FIGS. 10L and 10M, the method of manufacturing a display panel in an embodiment may include an operation of removing the second photoresist layer PR2.

Thereafter, referring to FIG. 10N, the method of manufacturing a display panel in an embodiment may include an operation of completing the display panel DP by forming the encapsulation organic layer OL and the upper encapsulation inorganic layer UIL. The encapsulation organic layer OL may be formed by applying an organic material in an inkjet method, but the disclosure is not limited thereto. The encapsulation organic layer OL provides a flattened upper surface. Thereafter, the upper encapsulation inorganic layer UIL may be formed by depositing an inorganic material. Therefore, the display panel DP including the base layer BL, the circuit element layer DP-CL, the display element layer DP-ED, and the encapsulation layer TFE may be formed.

An operation of forming the partition wall opening and the light-emitting opening corresponding to the light-emitting areas having different colors in the partition wall PW and the pixel definition layer PDL, an operation of forming the light-emitting elements providing different colors, and an operation of forming the lower encapsulation inorganic pattern covering the light-emitting elements providing different colors may be further performed between the operation of forming the lower encapsulation inorganic pattern LIL and the operation of completing the display panel DP. Therefore, as illustrated in FIG. 8, the display panel DP including the first to third light-emitting elements ED1, ED2, and ED3, the first to third capping patterns CPP1, CPP2, and CPP3, the first to third cover patterns CVP1, CVP2, and CVP3, the first to third dummy patterns DMP1, DMP2, and DMP3, and the first to third lower encapsulation inorganic patterns LIL1, LIL2, and LIL3 may be formed.

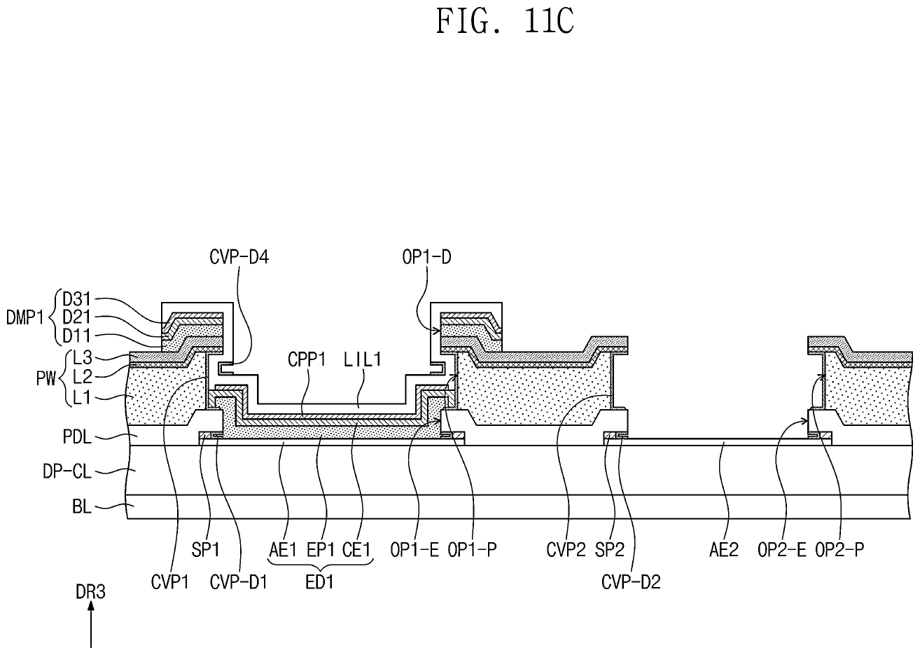

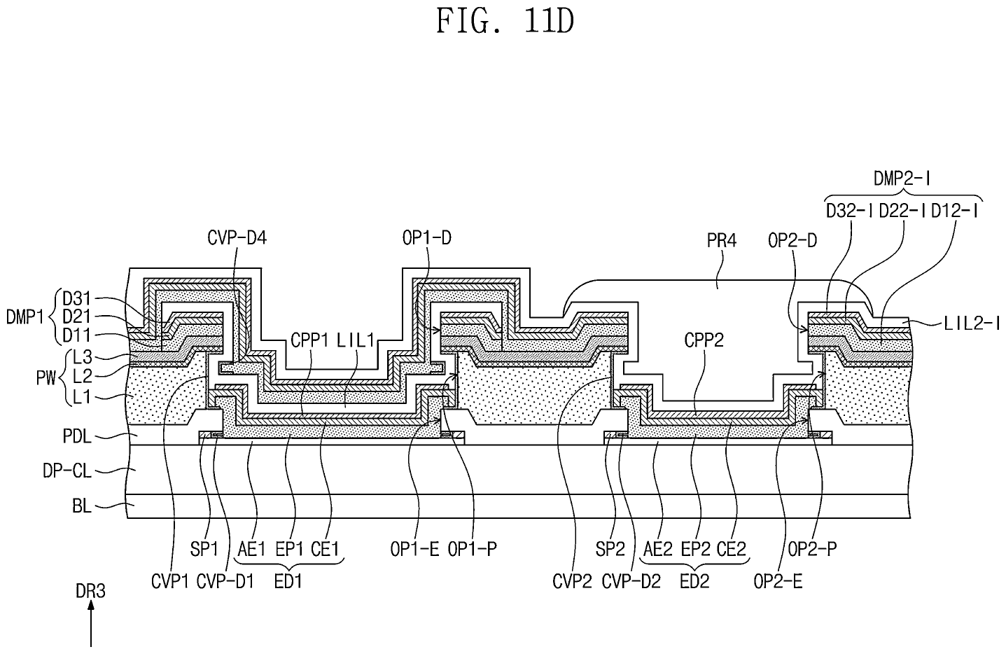

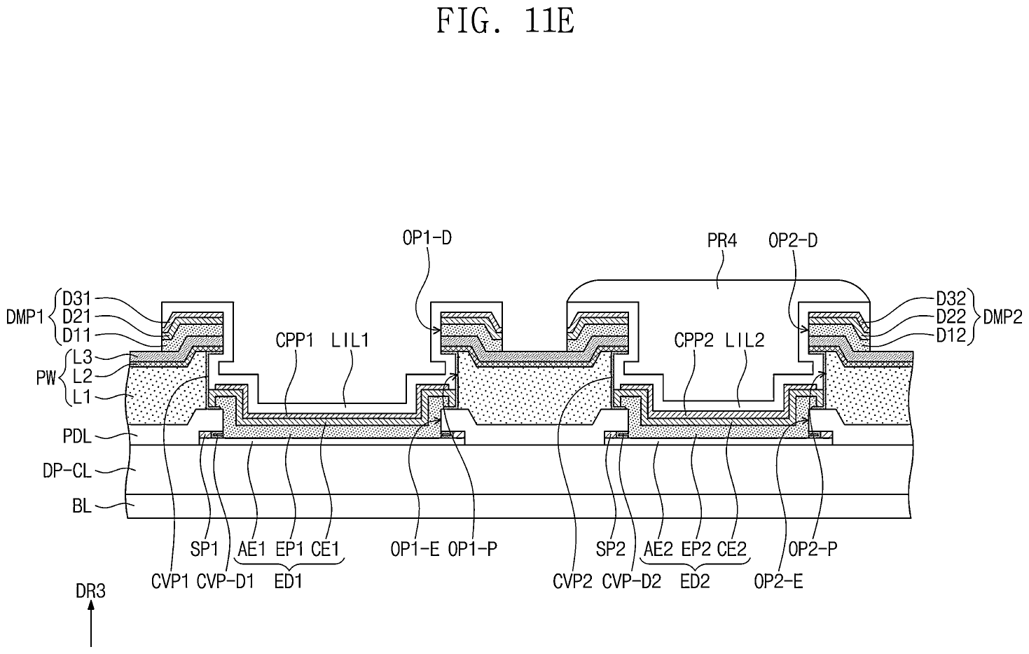

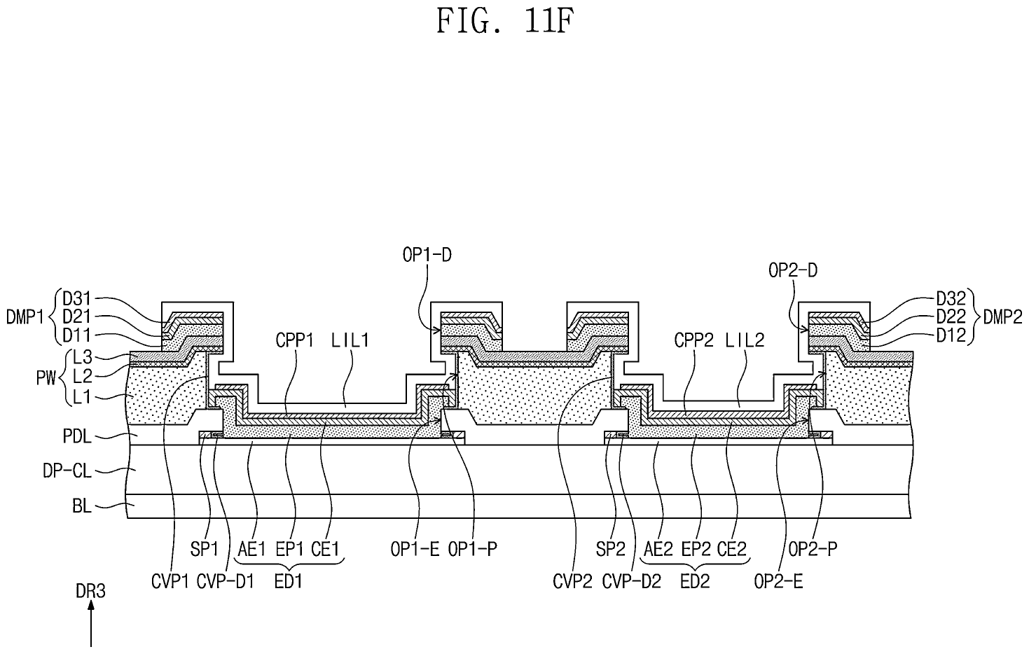

In the operation of the light-emitting elements providing different colors and the operation of forming the lower encapsulation inorganic pattern covering the light-emitting elements providing different colors will be described in detail with reference to FIGS. 11A to 11F.

FIGS. 11A to 11F are cross-sectional views illustrating an embodiment of some of operations of the method of manufacturing a display panel according to the disclosure. In description with reference to FIGS. 11A to 11F, the same/similar reference numerals are used for the same/similar components described in FIGS. 1 to 10M, and a duplicated description thereof will be omitted.

FIGS. 11A to 11F illustratively illustrate two light-emitting elements among the first to third light-emitting elements ED1, ED2, and ED3 described in FIG. 8. FIGS. 11A to 11F illustrate operations of manufacturing the second light-emitting element ED2 and the second lower encapsulation inorganic pattern LIL2 after forming the first light-emitting element ED1 and the first lower encapsulation inorganic pattern LIL1. The above description of FIGS. 10A to 10L may be equally applied to the operations of forming the first light-emitting element ED1 and the first lower encapsulation inorganic pattern LIL1.

FIGS. 11A to 11F illustratively illustrate the operations, and a formation order of the first to third light-emitting elements ED1, ED2, and ED3 is not limited to a particular embodiment.

Referring to FIG. 11A, an operation of forming a third photoresist layer PR3 on the partition wall PW. A second photo opening OP2-R overlapping the second anode AE2 may be defined in the third photoresist layer PR3.

Thereafter, an operation of defining the second partition wall opening OP2-P in the partition wall PW, an operation of defining the second light-emitting opening OP2-E in the pixel definition layer PDL, and an operation of defining the second sacrificial opening OP2-S in the second sacrificial pattern SP2 may be performed.

The descriptions of the first and second etching operations described above with reference to FIGS. 10D and 10E may be similarly applied to the operation of forming the second partition wall opening OP2-P on the partition wall PW.

The description of the third etching operation described above with reference to FIG. 10F may be similarly applied to the operation of the second light-emitting opening OP2-E on the pixel definition layer PDL, and the description of the fourthly etching operation described above with reference to FIG. 10G may be similarly applied to the operation of forming the second sacrificial opening OP2-S on the second sacrificial pattern SP2.

At least a portion of the second anode AE2 may be exposed by the second partition wall opening OP2-P and the second light-emitting opening OP2-E, and an area of the second anode AE2 exposed by the second light-emitting opening OP2-E may be defined as the second light-emitting area PXA-G (refer to FIG. 8).

Thereafter, referring to FIG. 11B, an operation of removing the third photoresist layer PR3 (refer to FIG. 11A) and an operation of depositing a second preliminary cover pattern CVP2-I may be performed. The description related to the process of depositing the first preliminary cover pattern CVP1-I described above with reference to FIG. 10H may be similarly applied to the operation of depositing the second preliminary cover pattern CVP2-I.

The second preliminary cover pattern CVP2-I may cover all surfaces exposed in the second partition wall opening OP2-P, the second light-emitting opening OP2-E, and the second sacrificial opening OP2-S. Further, the second preliminary cover pattern CVP2-I may cover all the upper surface of the partition wall PW exposed from the first dummy pattern DMP1, the first lower encapsulation inorganic pattern LIL1, and the first dummy pattern DMP1.

Thereafter, referring to FIGS. 11B and 11C, an operation of patterning the second preliminary cover pattern CVP2-I so that the second cover pattern CVP2 is formed from the second preliminary cover pattern CVP2-I may be performed. The description related to the fifthly etching operation described above with reference to FIG. 10I may be similarly applied to the operation of patterning the second preliminary cover pattern CVP2-I.

The operation of patterning the second preliminary cover pattern CVP2-I may be performed by the blanket etching process. That is, the operation of patterning the second preliminary cover pattern CVP2-I may be performed without a separate process of forming a photoresist layer. Therefore, the second cover pattern CVP2 and the second dummy cover pattern CVP-D2 may be formed from the second preliminary cover pattern CVP2-I. Further, in an embodiment, a fourth dummy cover pattern CVP-D4 disposed inside the second partition wall opening OP2-P may be further formed from the second preliminary cover pattern CVP2-I. The fourth dummy cover pattern CVP-D4 may be disposed in a portion of the first lower encapsulation inorganic pattern LIL1, which is recessed and stepped toward the first partition wall layer L1.

In an embodiment according to the disclosure, the recessed step may not be formed inside the first lower encapsulation inorganic pattern LIL1, and in this case, the fourth dummy cover pattern CVP-D4 may not also be formed.

Thereafter, referring to FIG. 11D, an operation of forming the second light-emitting pattern EP2, an operation of forming the second cathode CE2, an operation of forming the second capping pattern CPP2, and an operation of forming a second preliminary lower encapsulation inorganic pattern LIL2-I may be performed.

The description related to the process of depositing the first light-emitting pattern EP1, the first cathode CE1, and the first capping pattern CPP1 described above with reference to FIG. 10J may be similarly applied to the operations of forming the second light-emitting pattern EP2, the second cathode CE2, and the second capping pattern CPP2. The operation of forming the second capping pattern CPP2 may be omitted.

The second anode AE2, the second light-emitting pattern EP2, and the second cathode CE2 may constitute the second light-emitting element ED2.

In an embodiment, in the operation of forming the second light-emitting pattern EP2, the (1-2)^{th} preliminary dummy layer D12-I spaced apart from the second light-emitting pattern EP2 may be formed together. In the operation of forming the second cathode CE2, a (2-2)^{th} preliminary dummy layer D22-I spaced apart from the second cathode CE2 may be formed together. In the operation of forming the second capping pattern CPP2, the (3-2)^{th} preliminary dummy layer D32-I spaced apart from the second capping pattern CPP2 may be formed together.

The (1-2)^{th} to (3-2)^{th} preliminary dummy layers D12-I, D22-I, and D32-I may constitute a second preliminary dummy pattern DMP2-I. In an embodiment, a portion of the second preliminary dummy pattern DMP2-I may be disposed on the partition wall PW, the other portion of the second preliminary dummy pattern DMP2-I may be disposed inside the first partition wall opening OP1-P, and thus the first lower encapsulation inorganic pattern LIL1 may be covered. The second dummy opening OP2-D corresponding to the second partition wall opening OP2-P may be defined in the second preliminary dummy pattern DMP2-I.

The description related to the process of depositing the first preliminary lower encapsulation inorganic pattern LIL1-I described above with reference to FIG. 10K may be similarly applied to the operation of forming the second preliminary lower encapsulation inorganic pattern LIL2-I. In an embodiment, a portion of the second preliminary lower encapsulation inorganic pattern LIL2-I may cover the second cathode CE2 inside the second partition wall opening OP2-P, and the other portion of the second preliminary lower encapsulation inorganic pattern LIL2-I may cover the second preliminary dummy pattern DMP2-I.

Thereafter, an operation of forming a fourth photoresist layer PR4 on the second preliminary lower encapsulation inorganic pattern LIL2-I may be performed. The fourth photoresist layer PR4 may be formed in the form of a pattern overlapping the second anode AE2 and the second light-emitting opening OP2-E and may be formed so as not to overlap the first anode AE1 and the third anode AE3 (refer to FIG. 8).

Thereafter, referring to FIGS. 11D and 11E, an operation of patterning the second preliminary lower encapsulation inorganic pattern LIL2-I to form the second lower encapsulation inorganic pattern LIL2 and an operation of patterning the second preliminary dummy pattern DMP2-I to form the second dummy pattern DMP2 may be performed. The description related to the sixthly etching operation described above with reference to FIG. 10I may be similarly applied to the operation of patterning the second preliminary lower encapsulation inorganic pattern LIL2-I, and the description related to the seventhly etching operation described above with reference to FIG. 10L may be similarly applied to the operation of patterning the second preliminary dummy pattern DMP2-I.

In the operation of patterning the second preliminary lower encapsulation inorganic pattern LIL2-I, the fourth photoresist layer PR4 is used as a mask, a portion of the second preliminary lower encapsulation inorganic pattern LIL2-I overlapping the first anode AE1 and the third anode AE3 (refer to FIG. 8) is removed, and thus the second lower encapsulation inorganic pattern LIL2 in the form of a pattern overlapping the second anode AE2 may be formed.

In the operation of patterning the second preliminary dummy pattern DMP2-I, the fourth photoresist layer PR4 is used as the mask, a portion of the second preliminary dummy pattern DMP2-I overlapping the first anode AE1 and the third anode AE3 (refer to FIG. 8) is removed, and thus the second dummy pattern DMP2 in which the second dummy opening OP2-D is defined may be formed.

In detail, as portions of the (1-2)^{th}, (2-2)^{th}, and (3-2)^{th} preliminary dummy layers D12-I, D22-I, and D32-I, which overlap the first anode AE1 and the third anode AE3 (refer to FIG. 8), are removed, the (1-2)^{th}, (2-2)^{th}, and (3-2)^{th} dummy layers D12, D22, and D32 are formed, and the (1-2)^{th}, (2-2)^{th}, and (3-2)^{th} dummy layers D12, D22, and D32 may constitute the second dummy pattern DMP2.

In an embodiment, in the operation of patterning the second preliminary dummy pattern DMP2-I, the fourth dummy cover pattern CVP-D4 disposed inside the first partition wall opening OP1-P may be removed together.

Thereafter, referring to FIGS. 11E and 11F, an operation of removing the fourth photoresist layer PR4 may be performed.

Through the operations of FIGS. 11A to 11F, the second light-emitting element ED2 and the second lower encapsulation inorganic pattern LIL2 may be formed, and although not illustrated, thereafter, the third light-emitting element ED3 (refer to FIG. 8) and the third lower encapsulation inorganic pattern LIL3 (refer to FIG. 8) may be formed in manners similar to the operations described in FIGS. 11A to 11F.

According to the disclosure, a display panel having improved process reliability and easy implementation of a substantially high resolution may be provided because a patterned light-emitting pattern may be provided without a metal mask.

According to the disclosure, a partition wall having an undercut shape and including first and second partition layers and a cover pattern in contact with a lower surface of the second partition wall layer protruding from the first partition wall layer are provided, and thus a cathode may be electrically connected to the partition wall through the cover pattern. Accordingly, even when an oxide film is formed on an interface of the first partition wall layer, the oxide film may not affect an increase in contact resistance between a cathode and a partition wall or occurrence of an electrical contact failure. Thus, the display panel having improved process ease, and at the same time, improved electrical reliability and improved display efficiency may be provided.

According to the disclosure, a method of manufacturing a display panel, which may form a light-emitting element having easy implementation of a substantially high resolution and improved process reliability, may be provided. Further, the method of manufacturing a display panel, which has improved process ease, and at the same time, improved electrical reliability and improved display efficiency, may be provided.

Although the description has been made above with reference to an embodiment of the disclosure, it may be understood that those skilled in the art or those having ordinary knowledge in the art may variously modify and changes the disclosure without departing from the spirit and technical scope of the disclosure described in the appended claims. Accordingly, the technical scope of the disclosure is not limited to the detailed description of the specification but should be defined by the appended claims.

What is claimed is:

1. A display panel comprising:
a base layer;
a first anode disposed on the base layer;
a pixel definition layer in which a first light-emitting opening exposing at least a portion of the first anode is defined and which is disposed on the base layer;
a partition wall which includes a first partition wall layer and a second partition wall layer disposed on the first partition wall layer, in which a first partition wall opening corresponding to the first light-emitting opening is defined, and which is disposed on the pixel definition layer;
a first cover pattern disposed inside the first partition wall opening;
a first cathode in contact with the first cover pattern and disposed on the first anode; and
a first light-emitting pattern disposed between the first anode and the first cathode,
wherein the second partition wall layer protrudes from the first partition wall layer so that a lower surface of the second partition wall layer is exposed, and
the first cover pattern is in contract with an exposed portion of the lower surface of the second partition wall layer and overlaps an entirety of a portion of the second partition wall layer, which protrudes from the first partition wall layer, in a plan view.

2. The display panel of claim 1, wherein the first partition wall layer includes a first inner surface defining a first area of the first partition wall opening, and the second partition wall layer includes a second inner surface defining a second area of the first partition wall opening, and
a width of the second area in one direction is smaller than a width of the first area in the one direction.

3. The display panel of claim 2, wherein the first cover pattern is disposed only in the first area and is not disposed in the second area.

4. The display panel of claim 2, wherein the first cover pattern includes:
a first portion covering an entirety of the exposed portion of the lower surface of the second partition wall layer; and
a second portion extending from the first portion and covering an entirety of the first inner surface.

5. The display panel of claim 4, wherein the first cover pattern further includes a third portion extending from the second portion and covering at least a portion of an upper surface of the pixel definition layer exposed from the first partition wall layer.

6. The display panel of claim 4, wherein the first cathode contacts the second portion.

7. The display panel of claim 2, wherein the first cover pattern includes:
a first portion covering an entirety of the exposed portion of the lower surface of the second partition wall layer; and
a second portion extending from the first portion and covering an entirety of an oxide film formed on the first inner surface.

8. The display panel of claim 1, wherein the first cover pattern has a closed-line shape in the plan view.

9. The display panel of claim 1, wherein the first partition wall layer includes one of a conductive material and an insulating material, and
each of the second partition wall layer and the first cover pattern includes a conductive material.

10. The display panel of claim 9, wherein the second partition wall layer includes titanium nitride, and
the first cover pattern includes any one of tungsten, molybdenum, and titanium nitride.

11. The display panel of claim 1, wherein the partition wall further includes a third partition wall layer disposed on the second partition wall layer.

12. The display panel of claim 11, wherein a modulus of the third partition wall layer is greater than a modulus of the second partition wall layer.

13. The display panel of claim 1, wherein a thickness of the first cover pattern is 100 angstroms or less.

14. The display panel of claim 1, further comprising:
a second anode disposed on the base layer and spaced apart from the first anode;
a second cover pattern spaced apart from the first cover pattern;
a second cathode disposed on the second anode and in contact with the second cover pattern; and
a second light-emitting pattern disposed between the second anode and the second cathode,
wherein a second light-emitting opening exposing at least a portion of the second anode is further defined in the pixel definition layer,
a second partition wall opening corresponding to the second light-emitting opening is further defined in the partition wall, and
the second cover pattern is disposed inside the second partition wall opening.

15. The display panel of claim 1, further comprising:
a sacrificial pattern which is disposed on the first anode, an entirety of which is covered by the pixel definition layer and in which a sacrificial opening corresponding to the first light-emitting opening is defined; and
a dummy cover pattern which is disposed inside the sacrificial opening, an entirety of which is covered by the pixel definition layer, and which is spaced apart from the first cover pattern.

16. A method of manufacturing a display panel, the method comprising:
providing a preliminary display panel including a base layer, an anode disposed on the base layer, a pixel definition layer which is dispose on the base layer and in which a light-emitting opening exposing at least a portion of the anode is defined, and a partition wall which includes a first partition wall layer disposed on the pixel definition layer and a second partition wall layer disposed on the first partition wall layer and in which a partition wall opening corresponding to the light-emitting opening is defined;
depositing a preliminary cover pattern on the preliminary display panel;
patterning the preliminary cover pattern so that a cover pattern disposed inside the partition wall opening is formed from the preliminary cover pattern;
forming a light-emitting pattern on the anode; and
forming a cathode in contact with the cover pattern on the light-emitting pattern,
wherein the second partition wall layer protrudes from the first partition wall layer so that a lower surface of the second partition wall layer is exposed,
in the depositing the preliminary cover pattern, the preliminary cover pattern is deposited to contact an exposed portion of the lower surface of the second partition wall layer, and
the patterning the preliminary cover pattern is performed through a blanket etching process.

17. The method of claim 16, wherein the depositing the preliminary cover pattern is performed through an atomic layer deposition process.

18. The method of claim 16, wherein the patterning the preliminary cover pattern is performed through a dry etching method.

19. The method of claim 16, wherein the partition wall opening includes a first area defined by an inner surface of the first partition wall layer and a second area defined by an inner surface of the second partition wall layer, and
in the patterning the preliminary cover pattern, a portion of the preliminary cover pattern, which is disposed in the second area and the light-emitting opening and another portion of the preliminary cover pattern, which is disposed on the partition wall, are removed, and thus the cover pattern is disposed only in the first area.

20. The method of claim 16, wherein the first partition wall layer includes one of a conductive material and an insulating material, and
each of the second partition wall layer and the cover pattern includes a conductive material.
